(19) United States
(12) Patent Application Publication
(10) Pub. No.: US 2005/0024143 A1
(43) Pub. Date: Feb. 3, 2005

(54) Analog electronic device

(75) Inventor: Ted Humphrey, Clearwater, FL (US)

Correspondence Address: Ted Humphrey, Suite 358, 1497 Main Street, Dunedin, FL, 34698, US

(73) Assignee: Electronic Topologies Incorporated

(21) Appl. No.: 10/627,670

(22) Filed: Jul. 28, 2003

(51) Int. Cl. H03F 3/45

(52) U.S. Cl. 330/255

(57) ABSTRACT

An analog electronic building block for the design of electronic circuits leading to new topologies for amplifiers, cascoding, buffers, regulators and digital circuits. The new building bock has 4 terminals. The device uses the synergy that comes from connecting two like polarity transistors in a certain way. The device uses two transistors connected with the collector of a first transistor (Q1) connected to the base/gate of a second transistor (Q2) and the base of the first transistor connected to the emitter/source of the second transistor. The device opens up a whole new range of operation because the control exerted by the device is dictated by two of the four terminals and control is shared and passed from one to the other of the two terminals depending of the impedances of the input signals. These two terminals are the emitter of the first transistor and the base of the first transistor, which is, as noted, connected to the emitter/source of the second transistor. These two terminals can also act as outputs of the device depending on the exterior configuration and impedances. The device takes advantage of the inherent strengths of the bipolar transistor. The device forces the bipolar transistor to operate in the current domain and not the voltage domain as is generally done. The device also allows for increased control of MOSFET transistors. This complex interaction and synergy give rise to greater power of design and leads to new advanced topologies for amplifiers, buffers, cascoding applications, regulators and even digital circuits.

### CROSS-REFERENCE TO RELATED APPLICATIONS

This patent claims in one of its dependant claims the use of the proposed device to create an amplifier where the amplifier can under certain conditions be viewed as a current amplifier which is the subject of a related co-pending patent application.

In more detail, the other co-pending application is titled “Symmetrical Current Amplifier” submitted by Ted Humphrey in July 2003. Under certain conditions, claims 6, 7, 8 and 9 of this patent titled “Analog Electronic Device” and FIGS. 13, 14, 15 and 16 (and some later numbered Figures which include an amplifier), have the appearance of a current amplifier. This condition appears when the amplifiers are being driven by signals classified as currents rather than voltages. Such a classification is determined by the impedance of the signal. Under these conditions, the output current is either dependent on the input current or the difference of input currents. The amplifier designs taught in this patent depend on claims 1, 2 and/or 3 and the unique relationship or synergy that has been discovered about this connection of two transistors. These teachings are not included in the related co-pending application and are not obvious from that application. Therefore the amplifiers taught in this patent could not be included in that patent. These teachings show new unique ways to design an amplifier using the basic device, the core of this patent, that are an improvement over what could be designed before this invention. But the design of amplifiers is not the thrust of this patent. The thrust of this patent is that there is a building block that can be used in many different ways to design an array of circuits. There is no common structure between the two patnets.

### FIELD OF INVENTION

This invention relates to the design of electronic circuits and proposes a new building block that makes it easier to design complex analog circuits and improve their performance while simplifying them.

### PRIOR ART

There are four areas of prior art to examine. Also a quick statement concerning the dependant claims.

The four areas are:
1) The Darlington U.S. Pat. No. 2,663,806
2) Current sources
3) Current mirrors
4) Current limit circuits.

### The Darlington Patent

The first is the patent for the “Darlington” configuration. U.S. Pat. No. 2,663,806 dated Dec. 22, 1953 by Sidney Darlington. This is a very famous patent. The Darlington configuration has been widely taught and is included in all electronics books.

In said patent, there are three drawings that are not covered by the claims of said patent. These are FIGS. 6, 6A and 7. All the claims involve the language “connecting two like electrodes” whereas 6, 6A and 7 do not include such structure.

FIG. 6 in the Darlington patent is reproduced in FIG. 1 of this patent for reference.

There is a discussion of FIGS. 6, 6A and 7 in the body of that patent in column 6 lines 10-61. The discussion talks of the constants for the “equivalent single transistor” being similar to those of a single transistor and of the collector being fed by a high impedance and thus having low drift. The circuit as drawn and explained could only work in VERY special cases where currents were VERY small. There is a problem with the connection of b2 and c1 in FIG. 1 (FIG. 6 in earlier patent). We will use the general convention that current flow is from a more positive point to a less positive (more negative) point. This is discussed on page 2 in the reference book The Art of Electronics by Hororwitz and Hill published by Cambridge University Press. We also have Kirchhoff's Rule from page 3 of said reference “The sum of the currents into a point in a circuit equals the sum of the currents out”. Also from The Art of Electronics page 63, we see that, with an NPN transistor, current flows into the base and out the emitter and into the collector and out the emitter, i.e. Both I_{c} and I_{b} flow to the emitter. Iₑ is the sum of I_{c} and I_{b}. This is the active region of a transistor. FIGS. 6 (and 6A) of the Darlington patent as taught in that patent breaks Kirchhoff's Rule; as both the collector of the first transistor and the base of the second transistor expect to sink current. There is nothing connected to this point that can source the offsetting current needed to satisfy Kirchhoff's Rule. The patent explains some state that the circuit is in that is not the active region. In this state, the said patent gives us FIG. 6A as a composite. Again, the flow of current would be into b and out of e, a condition whereby the flow of current internal to the device would flow into e₁ and out of b₁ and into e₁ and out of c₁. A condition where only VERY small amounts of current could ever actually flow and a condition that is not all that useful.

The Darlington patent teaches that usage for FIG. 6, 6A and 7, of that patent, is to create a composite transistor with better properties. The Darlington patent teaches a composite transistor where current would normally flow into the “b” terminal of FIGS. 6, 6A and 7 of that patent. This would imply that current would then flow into the emitter of an NPN transistor and out of the base terminal. This is contrary to the normally functioning of an NPN transistor. In fact, I have never seen in the prior art any usage for the circuit in FIG. 6, 6A and 7 as taught in the Darlington patent. That is over a period of 50 years. This in contrast with the overwhelming use of the rest of the Darlington patent.

Beyond the basic lack of the circuit in FIG. 6 of the Darlington patent to work in some useful manner, the patent does not teach any of the invention taught in this current patent. In particular, there is no teaching in the Darlington patent of how to use the element to build an amplifier, a buffer, a digital circuit or use as a cascode unit and there is no teaching in this current patent of the creation of a composite transistor. The structure may look similar in the drawing but the function and results are entirely different.

This patent is an improvement, in that it does teach how to use this proposed configuration in a useful & workable manner. Per the rules, a patent must show/teach another how to build something useful. Furthermore, the claims of this patent are an improvement and refinement to any possible reference to the topologies included in this patent in the Darlington patent. The teachings of this patent are not taught in the Darlington patent, nor do they follow from anything taught in the Darlington patent.

### Current Sources

The second area is “current sources” or “constant current sources”. See FIGS. 2a-f. Most of these circuits have been known and used for at least 35 years. These start simply in 2a and become more complex. The basic problem handled in 2a-d is the base current to the two transistors with their emitters and bases connected together. The use of the extra transistor Q₂₁ in FIG. 2c is a better solution for an integrated circuit because a transistor takes much less space on the die than does a resistor. But the replacement of the resistor with a transistor doesn't perform any better, it just takes less die space. In fact, it loads the current source for the “reference” transistor Q₂₂. But the circuit doesn't have anywhere else to connect the base. The output current is less than that supplied by the resistor R₂₁. This difference in current is solved in FIG. 2d by placing the transistor in a different manner. Q₂₃ and Q₂₄ draw I₂₂−I_{b} and therefore Q₂₅ draws I₂₂−I_{b}−I_{b}+2I_{b=I}₂₂, where 122 is the current supplied by R₂₂. This is the sole reason for the use of Q₂₅ in FIG. 2d. In FIG. 2e, we see that the only property of Q₂₆ that is important is that it senses 600 mV. It acts as a switch to limit the current Q₂₇ pushes through the sensing resistor R₂₃. The constant current source circuit in FIG. 2e has not been used greatly as it doesn't work well in integrated circuits as it wastes power and involves the use of a resistor that dissipates heat and uses a lot of space on a wafer. FIG. 2f uses multiple (4) transistors all with the same quiescence current and much adding and subtracting of V_{be}'s to get a stable V_{be} and therefore a stable current. There is nothing special here in any of these circuits and certainly nothing that takes advantage of the special relationship that can occur when two transistors are connected as taught by this patent. This patent teaches an improvement in that it teaches the configuration of FIGS. 7 (and 8a-d) as a unique combination of transistors that is more useful than just creating constant current sources. This patent teaches the use of the proposed invention to create amplifiers, buffers, cascode other circuits, regulate voltages, create digital circuits, etc. In particular, if one examines the vast scope of the circuits that come from this invention, one can see the improvement that this patent teaches. These new circuits are not obvious as we can see by looking at the fact that the circuits in FIGS. 2c and 2e have been around at least 35 years and the teaching of this patent have never appeared. See FIGS. 11-29.

### Current Mirrors

FIGS. 3a-d show examples of current mirrors. FIG. 3a is the classic bipolar-transistor matched-pair current mirror. FIG. 3d is the Wilson current mirror. FIG. 3b is an early circuit as used in integrated circuits. FIG. 3c is a modification of 3b to replace the resistor R₃₁ with a transistor Q₃₁ which takes less space in the die of an integrated circuit. The Wilson current mirror is an improvement on circuits 3a and 3c in that the output current is equal to the input current. This is because Iₒᵤₜ=Iᵢₙ−I_{b}−I_{b}+2I_{b}=Iᵢₙ as noted above in section on current sources. FIG. 3b also has the property that the output current equals the input current but uses a resistor. The use of the bipolar transistor Q₃₁ in FIG. 3c is used solely to get rid of the resistor R₃₁ of FIG. 3b as the functioning of the circuit isn't quite as good as that of 3b. The usage of FIG. 3b was somewhat standard in integrated circuits at one time it appears but has been supplanted with the Wilson current mirror and its improvements. While there might appear to be some structure similarity between FIG. 3c and the current proposed patent, in that the base of transistor Q₃₁ is attached to the collector of the transistor receiving the reference current Q₃₂, it is by accident and not by the nature of the relationship of the two transistors. There is nothing in the usage that would lead one to see and use the relationship in some further useful manner.

### Current Limit Circuits

Current limit circuits are shown FIGS. 4a, 4b and 5a-d. FIGS. 4a and 4b are stylized circuits in that they aren't really seen in this form but add a diode in the collectors to make sure they conduce at the proper times. In practice, the circuits become different. While FIGS. 4a and 4b are simple examples, we generally see usage from FIGS. 5a-d. Only in FIGS. 4a and 4b, do we see any possible structure similarity to this proposed patent. With the introduction of a diode in the collectors, that possible similarity disappears. The current limit transistors Q₄₁ and Q₄₂ are meant to operate only in extreme situations and not continuously. They act as a switch. FIGS. 5b-d are from Fairchild's Voltage Regulator Handbook by Andy Adamain from 1978. FIG. 5a is representative of many IC current limit circuits. In FIGS. 5a-d, we see the same use of the current limit transistors Q₅₁, Q₅₂, Q₅₃, and Q₅₄, BUT none of the possible similarity of FIG. 4. This would lead us to believe that the secret to using the transistor in these circuits is that it can sense 600 mVolts easily. There is nothing in these usages that depends on the unique relationship or synergy that can exist between two transistors as shown in this patent. We see that the collector of the sensing transistor in these earlier circuits can be returned to many different places to effect its results. These earlier circuits work independently of whether the collector of the sensing transistor is returned to the base of the common emitter transistor whose current is being sensed. Further, in the usage as expressed in FIGS. 4a and 4b, when the collector of the sensing transistors Q₄₁ and Q₄₂ is returned to the base of the common-emitter transistors Q₄₃ and Q₄₄, the signal input to the common-emitter transistor (at what we call terminal 1 in FIG. 7) is a voltage driving a common emitter circuit. In contrast, in this patent application terminal 1 is fed by a current, generally a constant current. See claims 1, 2 and 3. So we see any possible structure similarity in the earlier circuits is by chance or accident and not by design and that the function and results are different than taught by this current proposed patent.

### Other Prior Art

Because all the dependent claims depend on claims 1, 2 or 3, they would by necessity be new and unique. Case in point, while there have been other amplifiers that have buffered the voltages to output transistors, the method of doing so in this patent is new, unique and an improvement. See FIG. 24. Due to the wide range of applications that can be created with the use of this patent, the scope would be very great. Because the factors of new and unique are determined by the validity of the independent claims, this application does not go into all the prior art that might exist in the areas of amplifiers, buffers, etc. None are known by the applicant which would interfere. Embodiments of the independent and dependent claims are shown and explained to show how they work and how they simplify the design of other circuits.

### SUMMARY OF THE INVENTION

This invention teaches an electronic building block that can be used to create other unique electronic circuits. This building block makes it easier to build complex analog circuits that are simpler with improved performance. The device uses two transistors connected with the collector of a first transistor (Q₁) connected to the base/gate of a second transistor (Q₂) and the base of the first transistor connected to the emitter/source of the second transistor. The strength of the invention is that it opens the door to more complex circuits that have not been envisioned before. It breathes new life into the bipolar transistor by taking advantage of the its strengths instead of compensating for its weaknesses. The building block and the more complex circuits that come spring from it, take advantage of the inherent nature of the bipolar transistor. The bipolar transistor is by nature a current amplifying device and not a voltage amplifying device. The device shows off a synergy that comes from the particular connection of two transistors. The device's performance changes depending on the impedances of the driving signals. The control passes from one terminal to another in a smooth manner that allows a great scope of usage therefore. The device also leads to much improved use of MOSFET transistors in amplifiers and buffers.

Symbols and Equations

The capital letter Q with a subscript represents transistors. Subscripts in the range 1-8, as shown in FIG. 8a-d, are reserved to indicate when the basic device is embedded in another application. If two devices of the same configuration are included in a circuit, an A or B is attached to the subscript. See FIG. 23 as an example. If multiple usage of the device is included in an application but in FIGS. 8a-d have different subscripts, then those subscripts will be used in the drawing. See FIG. 24. All other transistors have numbers greater than 100. Transistors with the same subscript perform a similar function in the different drawings. The circuits build on the simple ones.

A capital letter I with a subscript indicates a constant current source in the drawings. If the subscripts are the same, then the value of currents are the same. This value of current can be altered to change the performance of the circuit. It can be optimized for the desired usage of the circuit and the properties desired. Discussion of this is included in the DISCLOSURE OF INVENTION.

The Numbers 1-4 labeling a terminal or connection in a circuit simply represents the terminal numbers as detailed in claims 1 to 3. The capital letters A, B, C, D, E, F, G, H, and V are used to indicate connection to the world outside of the circuits. The letters A and B represent the inputs. C and D are outputs and are labeled such that a negative current/voltage “into” A or B will create a positive current/voltage from C or D respectfully and visa versa. E and F are internal summing points that may be exposed to the output world to allow for customizing the circuit parameters. G and H are input and output for the digital circuits. V with a subscript and a polarity indicate a connection to a supply voltage of some useful value. Vᵢₙ and Vₒᵤₜ indicate an input signal voltage and an output voltage.

Use of capital letters R and Z are used to represent an impedance, either simple or complex. The use of R is a special case of Z as it represents a simple resistance. Generally the two are used interchangeably in this patent. Generally, any time a resistor is shown, it could be a complex impedance rather than a simple resistance. For clarity, this document will try to state when it is important or when observations can be make about the nature of that impedance as it relates to the functioning of the amplifier.

In the same manner, the use of the word “source” is intended to include “sink” depending on the polarity of the transistors involved. Also, the words “accepts” and “produces” do not imply a direction of flow (current) or a polarity of voltage.

β always indicates the beta of a bipolar transistor and does not relate to feedback factors. It is generally in the range of 20 to 200. I generally estimate it at 100 for convenience.

Any equations included in this document are derived intuitively and are to show general properties of the circuit. They are first order approximations and are not meant to be necessarily a complete representation of the circuit. They are nevertheless offered as useful in understanding the workings of the circuit. As this is a brand new area of research, much work is yet to be done on an “academic” level fully detailing the properties of the circuits. This I leave to others as the included equations are sufficient for me and others to build workable/useful electronic devices.

### DESCRIPTION OF DRAWINGS

FIG. 1 shows prior art. It is a copy of FIG. 6 of the Darlington U.S. Pat. No. 2,663,806.

FIG. 2(a-f) shows prior art for current sources. These are discussed in detail in the above discussion of prior art.

FIG. 3(a-d) shows prior art for current mirror circuits. These are also discussed in detail in the above discussion of prior art.

FIGS. 4a and 4b show prior art circuits for current limiting.

FIG. 5 shows prior art for a variety of current limit circuits. These are discussed in detail in the above discussion of prior art.

FIG. 6 is a dream circuit that is non-functional. Used as a point of departure.

FIG. 7 shows the most simple embodiment of the teachings of this patent.

FIG. 8(a-d) shows different embodiments of claim 1.

FIGS. 9 and 10 are the basic device and a redrawn version that shows its function in a different way. These figures relate to claims 1, 2 and 3.

FIG. 11 shows the use of two devices cascoding an operation amplifier integrated circuit.

FIG. 12 is just redrawn to show the nature of the cascoding more clearly. Note that the drawing uses a basic embodiment in both polarities. These figures relate to claims 4 and 5.

FIG. 13 shows the use of the two devices to create an amplifier. This figure relates to claims 6, 7, 8, and 10.

FIG. 14 shows a further modification of FIG. 13 with more versatility. This figure relates to claims 6, 7, 9, and 10.

FIG. 15 shows an amplifier similar to that of FIG. 14 but created with the use of the invention as detailed in claim 3. This figure relates to claims 6, 7, and 9.

FIG. 16 shows an amplifier where all the transistors operate with the same quiescent current. This figure relates to claims 6, 7, and 9.

FIG. 17 shows the use of two devices of opposite polarity to create a buffer amplifier. This figure relates to claims 11, 12 and 13.

FIG. 18 is similar to FIG. 17 but uses the device as detailed in claim 3 to build a buffer. This figure relates to claims 11, 12 and 14.

FIG. 19 shows an amplifier from FIG. 14 driving a buffer from FIG. 17 to create a composite amplifier. This figure relates to claims 6, 7, 9, 11, and 17.

FIGS. 20-24 show the use of the device to create other topologies for buffer amplifiers.

FIG. 20 uses an extra transistor top and bottom to add even increased bias stability.

FIGS. 21 and 22 show how the device aids in the control of a MOSFET transistor in the building of a buffer.

FIG. 23 includes a voltage amplifier included as a front-end to a buffer with MOSFETs as primary output devices.

FIG. 24 shows not only the use of the device to create the buffer but shows additionally the use of the device as detailed on claim 3 to create a form of a floating power supply for the output devices. These figures relate to FIGS. 6, 7, 9, and 11.

FIG. 25 shows an amplifier buffer combination with differential inputs and MOSFET output devices. These figures relate to claims 4 and 11.

FIGS. 26 show a circuit using the device to create a voltage regulator. These figures relate to claims 6 and 15.

FIG. 27 shows a circuit using the device to create an OR gate. These figures relate to claims 16 and 17.

FIGS. 28 and 29 show circuits using the device to create an NOR gate. The circuits are different in their approach to making sure that input transistors are fully on with no input. These figures relate to claims 16, 18, and 19.

FIG. 30 shows a simplified circuit to aid in understanding some of the earlier circuits. It shows a positive rail current mirror that uses an amplifier to control a MOSFET.

FIGS. 31 show a “block” diagram to use when examining the performance of the amplifiers, to show external hookups to an amplifier and to show the names of the external components.

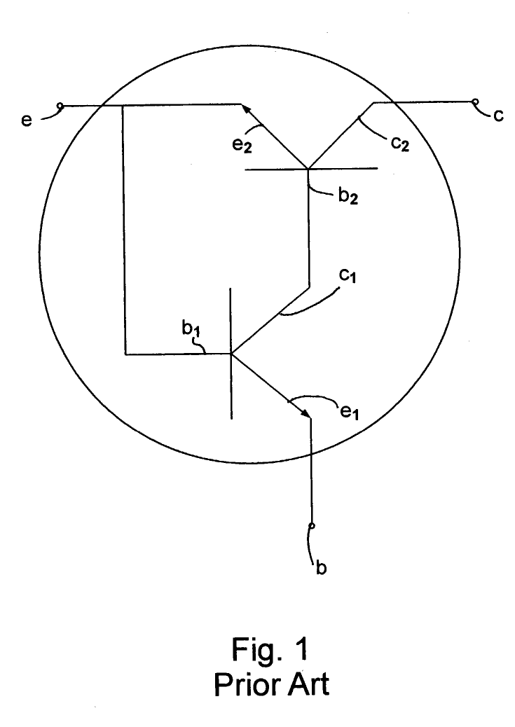

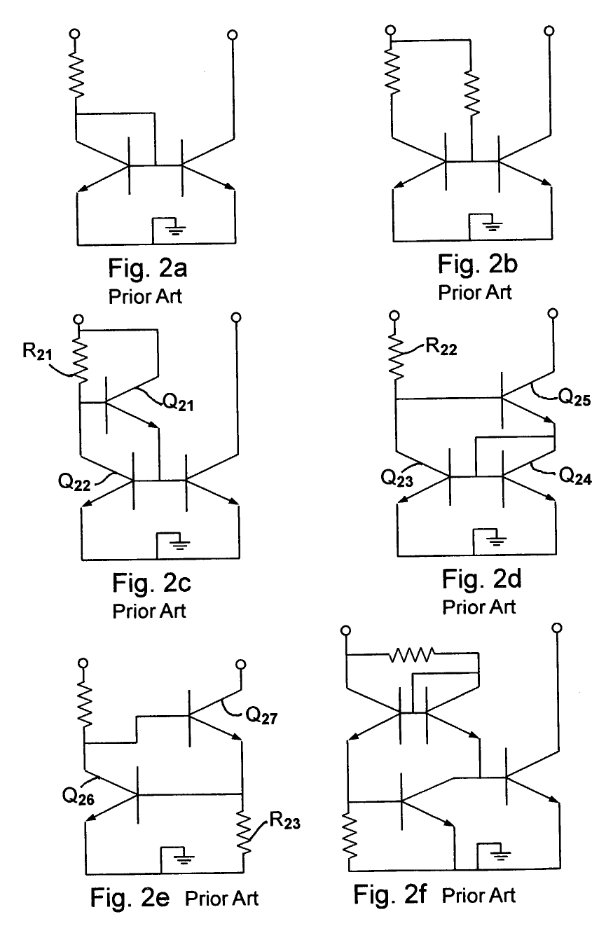

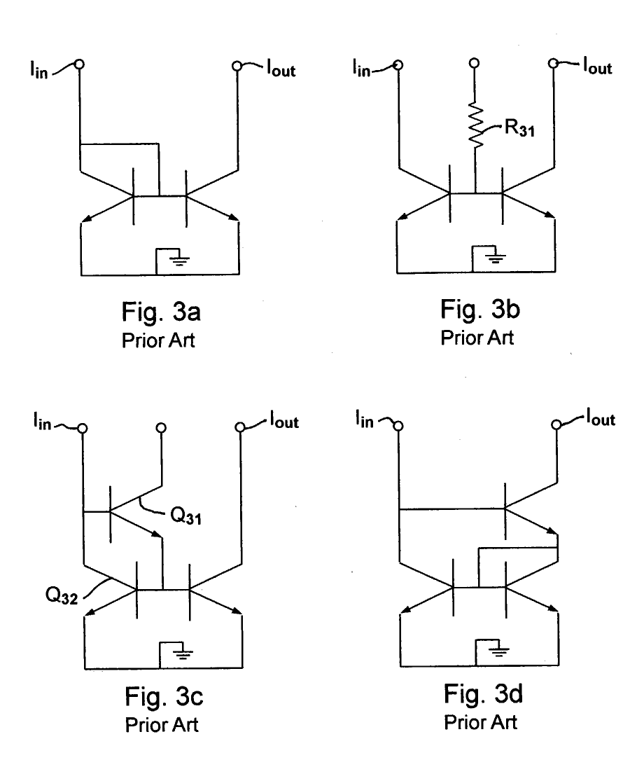

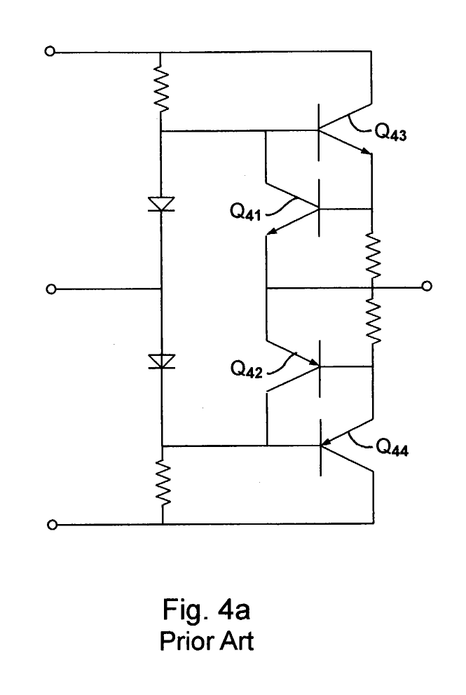

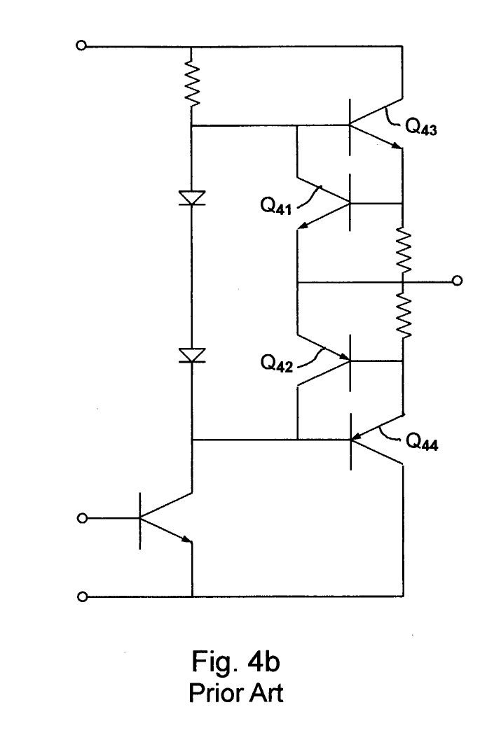

### DISCLOSURE OF INVENTION

While examining the subject of amplifying circuits and the weaknesses of different architectures, two advancements were made. This patent is the subject of one of those.

Using as a datum that bipolar transistors work best in a current mode, a new approach to amplifying was worked out.

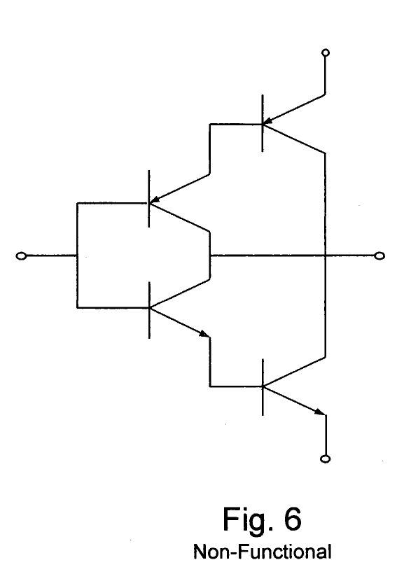

Attention kept going to the circuit of FIG. 6. A way just had to be figured out how to get it to work. Finally the solution as detailed in this patent became apparent.

It was clear that one had to work with current and handle items such as Miller Effect, hard saturation, Early effect, biasing instabilities, problems with level shifters, phase inverters, and buffers, etc.

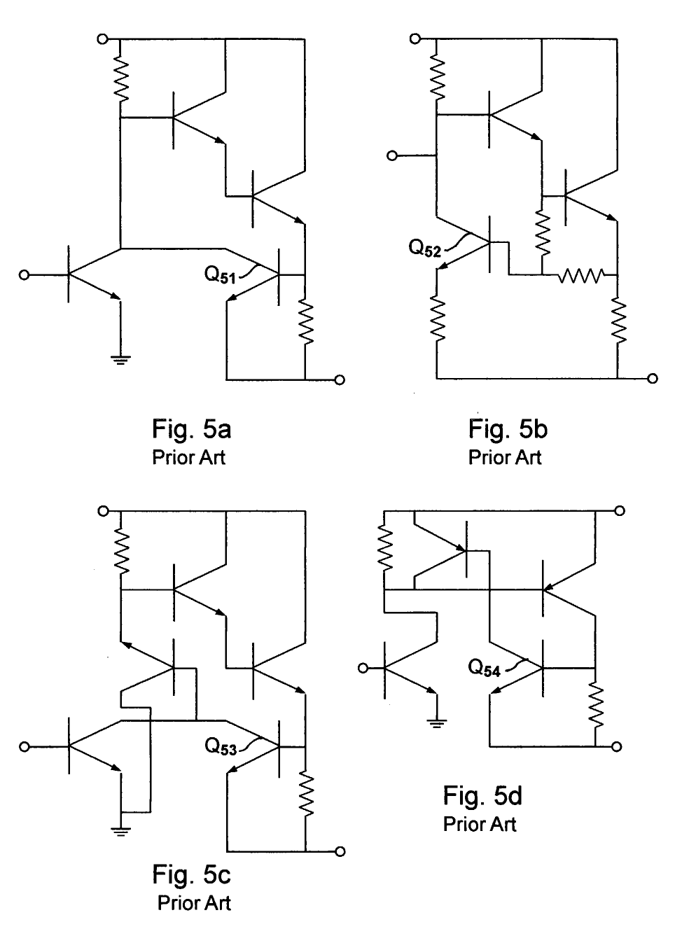

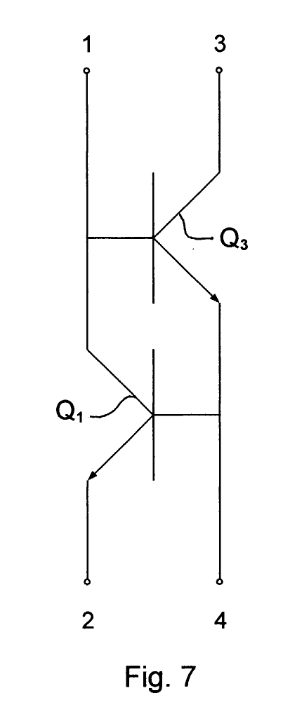

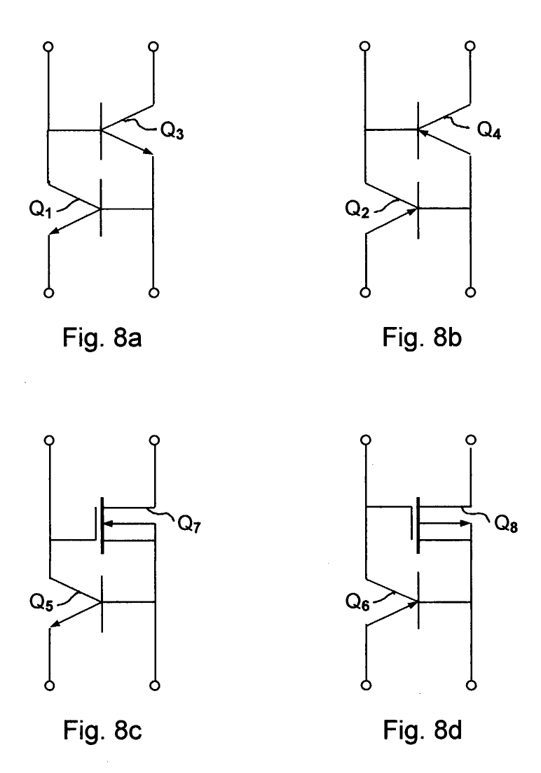

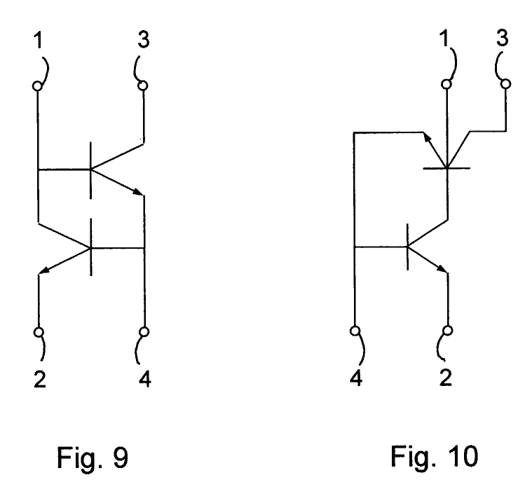

After many years of research and many 100s of schematics, some common elements/solutions started to keep coming up. One common set of elements became clear and is the basis of this patent. One of these elements is represented in FIG. 7. It is composed of Q₁ and Q₃ when it is made up of two NPN transistors. It is redrawn in FIGS. 8a-d to show both polarities and with both a bipolar transistor and a FET (MOSFET) transistor for the second transistor. Here we give labels that will be useful in later drawings to show when a version of the device is being used. In FIG. 8b, the transistors are labeled Q₂ and Q₄. In FIG. 8c, the transistors are labeled Q₅ and Q₇. In FIG. 5d, the transistors are labeled Q₆ and Q₈. It is also redrawn in FIGS. 9 and 10 to show a different look at the same thing. The circuit was the results of research into the design of amplifiers, buffers, cascoding circuits and voltage regulators. As it was the results of research into so many areas, it doesn't clearly come from one area more the others. Once the device started to become clear, it was checked out in the other areas and back and forth. What became clear is that there is a synergy of two transistors when connected as suggested by this patent. The device showed special properties of great advantage over the prior art.

The uses hereby detailed are not necessarily in the order they were discovered or even most logical but in an order that goes from simple to more complex embodiments.

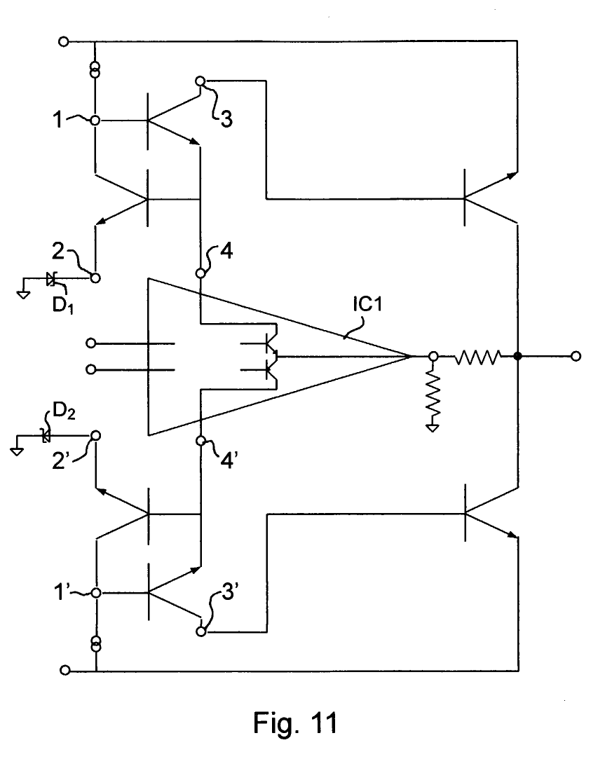

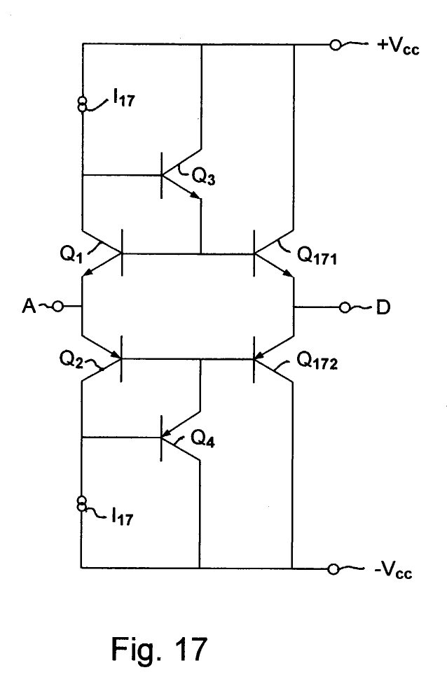

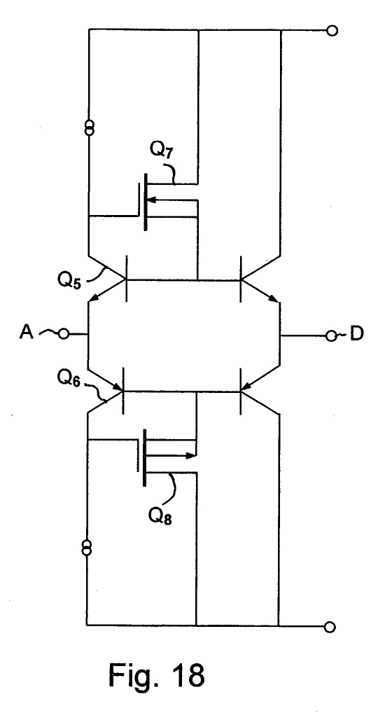

The basic embodiment shown in FIG. 7 is much more complex in action than it appears. There is a synergy involved in that the combination is far more than the sum of the parts. In practice, terminal 1 is supplied with a current, generally a constant current. Terminal 3 is an “output”. Terminal 3 output is affected by the device but the device is not affected by what occurs external to terminal 3 within reason. It is a high impedance. It draws a current that is determined by the device in response to what appears at all the other terminals. Terminals 2 and 4 are more complex. As an example, if the impedance at terminal 4 is much less than that at terminal 2, the voltage at terminal 4 will affect the voltage at terminal 2. As examples, see FIGS. 17, 18, or 21 when driving a heavy load. Because the current being driven into terminal 2 can't be “stopped” as it is a high impedance, it does affect the output current but not directly the voltage. Reversely, if terminal 2 is driven by a voltage (a low impedance) then it dictates the voltage at terminal 4. The current out of terminal 4 will be determined by the impedance (load) at terminal 4. See FIGS. 11, 13, 26. Most of the Figures/circuits are chameleon like in nature where the dominance changes depending of the external components. Almost any of the Figures fall into this mode. In fact when using feedback, the equations may come out easier, when examining the system in detail, from a current viewpoint rather than a voltage viewpoint. Under many conditions on a day to day basis, one can treat the amplifiers similar to common operational amplifiers. Many of the amplifiers will give better performance when treated similar to CFAs. When looking to set internal parameters or frequency compensation, it certainly is better to look to the circuit from a current aspect. Often, one can fix (lock to one value) input values to all but one terminal and let that one create all the change. Example, when used as a cascode circuit, setting the voltage at terminal 2 will set the voltage the voltage at terminal 4. Then any current variation at terminal 4 will be reflected by the same change at terminal 3. Just what one would want. Most of the circuits are more dynamic in nature and that is the real strength of the device. That synergy is what allows the device to be the core of so many circuits and do such a good job at it.

The embodiments as shown in FIGS. 7 and 8a-d and detailed above demonstrate examples of the means included in claim 1. These means from claim 1 are further illustrated in the other embodiments of the claims.

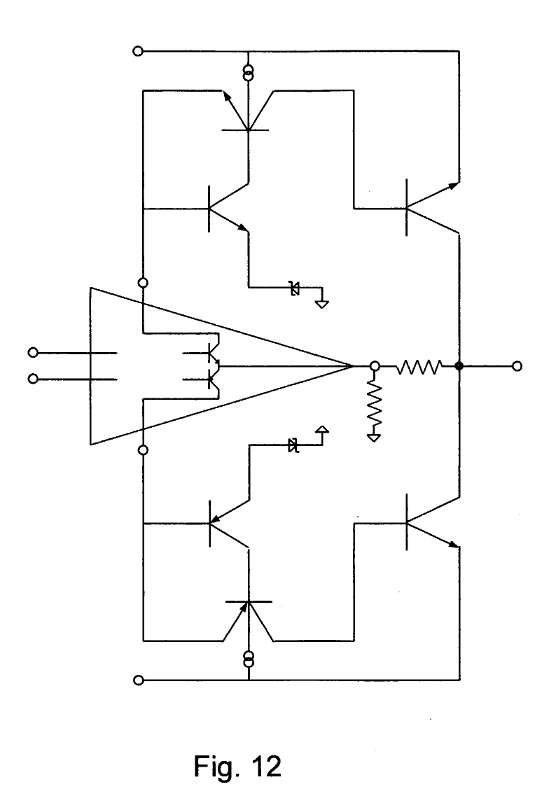

The device can be used to cascode any other device(s). This could extend from a simple transistor in an amplifier to the circuits of FIGS. 11 and 12. FIG. 11 (and 12) shows the use of two devices to cascode an integrated circuit operational amplifier IC1. Cascoding an integrated circuit is not new. Reference my own patent U.S. Pat. No. 4,797,633. But this proposed device gives much better performance in terms of lower impedance at the integrated circuit terminal 4, more accurate current drawn into the cascoding device at terminal 3 and improved frequency response as the internal “amplifying” transistor of the device is in its own right cascoded by the other transistor of the device. We see this in FIGS. 8a-d. These internal transistors of the device are labeled Q₁ and Q₃ for the positive polarity device and Q₂ and Q₄ for the negative polarity device in FIG. 8a-d. In FIGS. 8a and 8b, the above mentioned internal “amplifying” transistors are Q₁ and Q₂ and the internal “cascoding” transistors are Q₃ and Q₄. We see in use as a cascoding device that it is supplied a reference voltage at terminal 2. A constant current is supplied to terminal 1. Thus we get substantially a constant current through the reference unit which in this case is a zener diode D₁. A fixed voltage is then produced at terminal 4 and the current drawn by the integrated circuit is duplicated by the current drawn into terminal 3. This is similarly done for the negative supply voltage with the use of a device as marked 1′, 2′, 3′, 4′ and zener diode D₂. FIG. 12 is just redrawn to give a different look to the circuit. The zeners can be replaced with any suitable voltage reference.

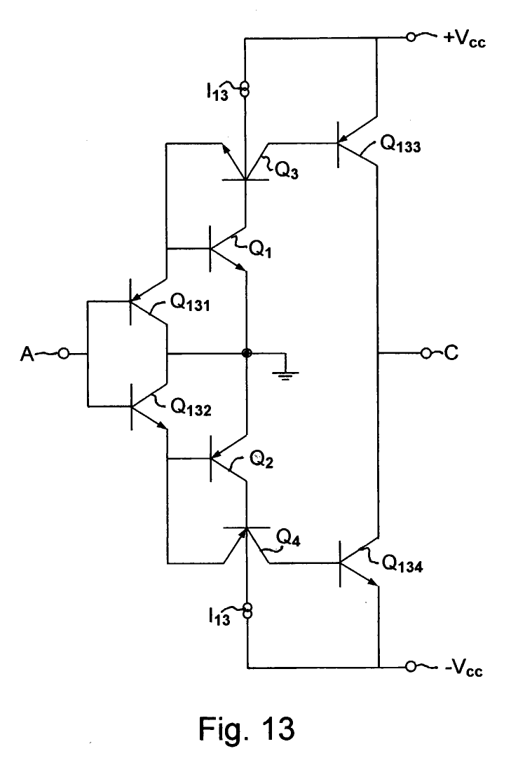

Through arrived at differently, one could look to FIG. 13 as being derived from FIG. 6 and the idea of being able to cascode the emitter to base and emitter to collector junctions. The input transistors are a current gain stage cascoded at about 600 mvolts. The quiescent current of transistors Q₁₃₁, Q₁ & Q₃ and Q₁₃₂, Q₂ & Q₄ are all substantially equal to the current produced by the current sources I₁₃. The current in the output transistors Q₁₃₃ (and Q₁₃₄) is then β₁₃₃ I₁₃ (and β₁₃₄ I₁₃). The input current is the difference of that required by the two input transistors to produce a zero output current. This is (((β₁₃₂ β₁₃₄−β₁₃₁ β₁₃₃)/β₁₃₁ β₁₃₂ β₁₃₃ β₁₃₄)*β₁₃₃*I₁₃). For a match of even 100%, i.e. 2 to 1 for β₁₃₂ β₁₃₄ to β₁₃₁ β₁₃₃ and β₁₃₄ to β₁₃₃, we get a figure of I₁₃/(2*β₁₃₁). By adjusting I₁₃ and matching product of the betas of the transistors, we can reduce the input current to an arbitrarily small value. When the amplifier is driven by a current, we can determine the current gain of the amplifier. Iₒᵤₜ=−Iᵢₙ*β₁₃₁* β₁₃₃. In practice, we can restate it in terms of voltage by looking to FIG. 31 with input B grounded, Vₒᵤₜ=−Iₒᵤₜ*R_{L}=−Iᵢₙ*β₁₃₁*β₁₃₃*R_{L}=−Vᵢₙ/Rᵢₙ*β₁₃₁*β₁₃₃*R_{L}. This gives us Aᵥₒₗ=Vₒᵤₜ/Vᵢₙ=−β₁₃₁*β₁₃₃*R_{L}/Rᵢₙ. We can determine the loop gain by dividing by the closed loop gain i.e. −R_{f}/Rᵢₙ. Thus loop gain is =β₁₃₁*β₁₃₃*R_{L}/R_{f}. The transresistance is β₁₃₁*β₁₃₃*R_{L}. or (β² R_{L}). This is similar that of a CFA or Current Feedback Amplifier. Transresistance for a typical CFA is 100 K. Our value above is normally much greater. One of the best discussions of current feedback amplifiers (CFA) is Burr Brown Application Bulletin #193 THE CURRENT-FEEDBACK OP AMP A HIGH SPEED BUILDIN BOLCK by Anthony D. Wang and Analog Circuit Design (Edited by Jim Williams) Chapter 25 Current-Feedback Amplifiers by Sergio Franco. Trying to compute a voltage gain of the amplifier is much more complex. It is not very informative and for most applications we can use the above formula. When operated as an inverting amplifier with a fixed voltage (generally ground), the amplifier follows the rules for a current feedback amplifier. Even when operated as a non-inverting amplifier, the amplifier operates as a CFA as regards to negative feedback. It accepts then a voltage input at the non-inverting input, but still has all the benefits of a CFA.

The input transistors Q₁₃₁ and Q₁₃₂ have a constant voltage across them of about 600 mV and draw current in the order of μAmps. The heat dissipated is therefore on the order of μWatts. The input transistors are the most important in determining the performance of the circuit. They can be chosen for high current gain, high frequency response, matching with the other input transistor, etc. When R_{f} is chosen to be approximately equal to β₁₃₃*R_{L}, then loop gain it approximately equal to β₁₃₁. The loop gain doesn't go to 1 until the F_{T} of the transistor. This is of the order of 100 to 1500 MHz. As the loop gain is only dependent on R_{f} and not Rᵢₙ, the amplifier could have a gain of 100 and still have a −3 db point of several hundred Mhz. Offset and input impedance are discussed in detail with later circuits. Most of the discussion is similar from one amplifier to another. Please note that the circuit in FIG. 13 has a −40 db roll off and therefore generally needs some kind of frequency compensation. In this circuit, the possible choices are a capacitor on the load or using slower transistors for the input transistors. Circuits to follow have more options for compensation. Even a capacitor on R_{f} could stabilize the circuit. It does so by extending the loop gain and roll off rate. It is very practical and useful.

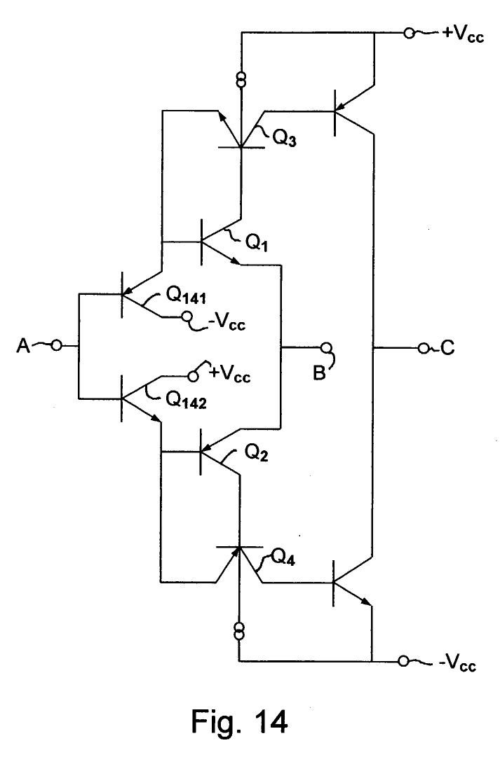

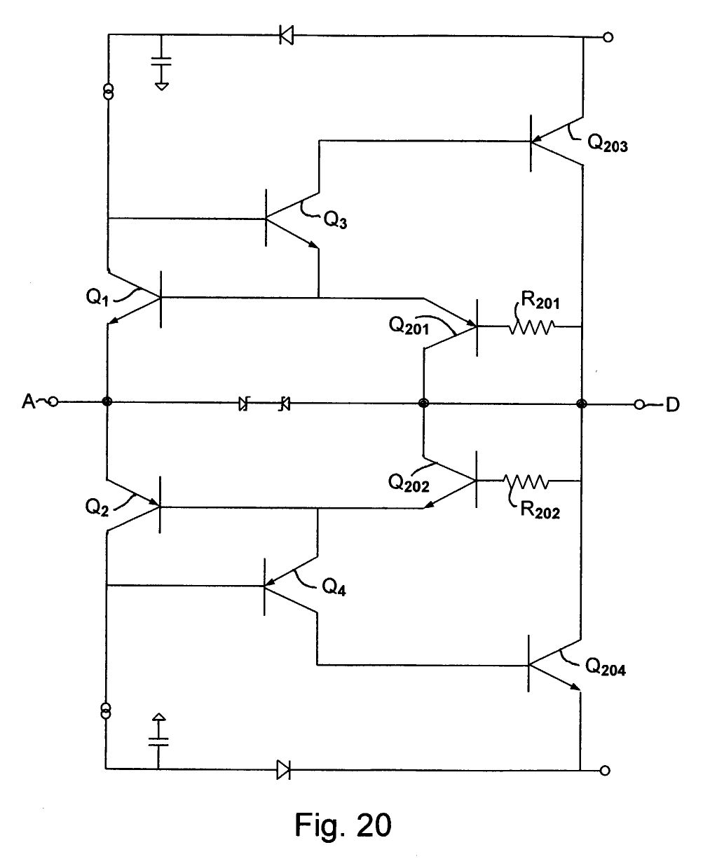

FIG. 14 is a modification of 13 to unlock the input(s) from ground and increase common mode range. By connecting the collectors of the input transistors Q₁₄₁ and Q₁₄₂ to suitable fixed supply voltages, we get an improved common mode voltage range for the input. We also see we can then unlock the connection of the emitters of transistors Q₁ & Q₂ from ground and use that point as another input; a non-inverting input. We now have a differential amplifier. We can use the equations for gain and loop gain in the discussion of FIG. 13. See FIG. 31 for connection of external components. Of course, there is only one feedback resistor, as there is only one output and therefore only one inverting input to be connected. By setting gain resistors for the inverting side, we get a circuit where the amplifier acts as a non-inverting amplifier with a fixed gain when driven by a voltage at the non-inverting input. When driven by a current, the response becomes much more complex and unpredictable. One could also, connect the inverting input to the output and we would have a buffer amplifier, i.e. an amplifier with a gain of +1. A variation of this is shown in FIG. 20.

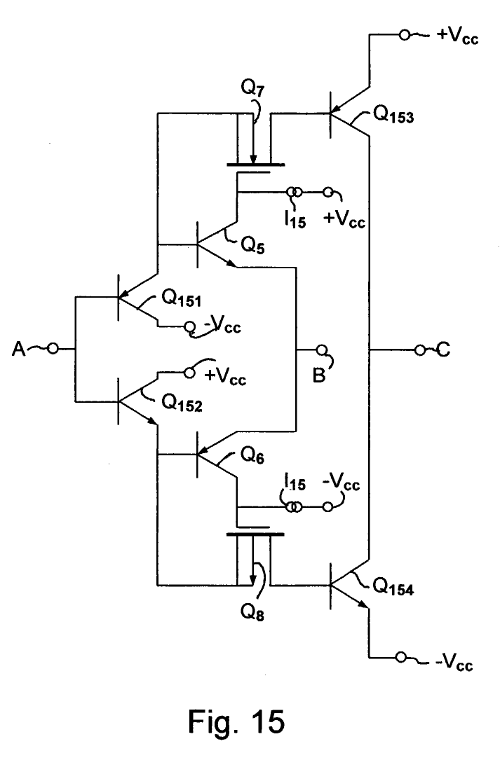

FIG. 15 is a modification of FIG. 14 showing the use of a MOSFET transistors Q₇ and Q₈ as detailed in claim 3. Transistors Q₁₅₁ and Q₁₅₂ are used for the input gain stage and Q153 and Q₁₅₄ are used for the output gain stage. The quiescence current of all the transistors is the same as in FIGS. 13 and 14. All the equations for gain are still the same. The advantage of this circuit is the increase of maximum current available to quiescence current. In FIGS. 13 (and 14) that ratio is limited to β₃ (or β₄) as the output current is limited to I₁₃*β₃*β₁₃₃. The available output current for FIG. 15 is limited only by the limits of the transistors and available input current as the output current is still Iₒᵤₜ=Iᵢₙ*β₁₅₁*β₁₅₃. With 1 mA current input, the circuit can still produce many Amperes of output current. This is very good for a circuit with little or no cross-over distortion. The reasons for the low distortion is that the transistors are driven with current and not voltage, only turn off under extreme conditions and don't relay on emitter follower circuits.

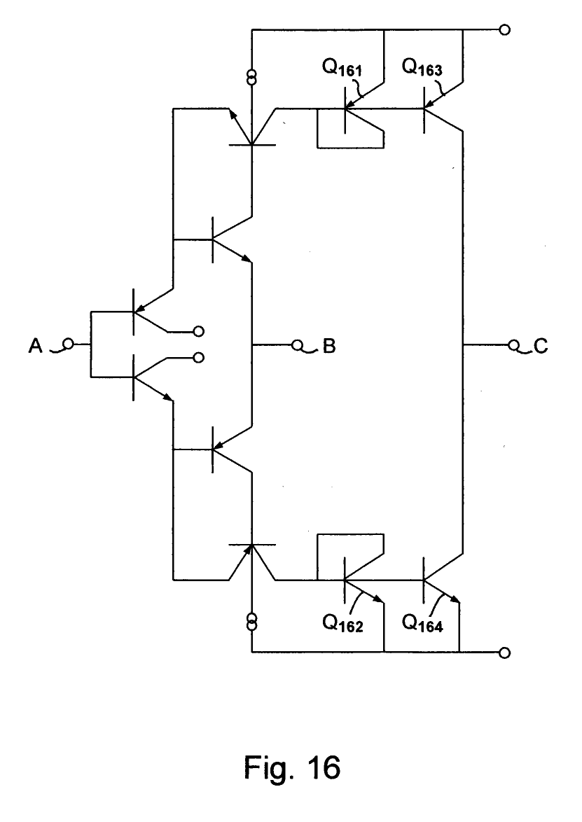

FIG. 16 is a modification of FIG. 14 showing an amplifier where all the transistors have the same quiescence current. To the output gain stage transistors Q₁₆₄ and Q₁₆₃ have been added two diode-connected transistors Q₁₆₁ and Q₁₆₂. As the output quiescence current is reduced by a factor of β the circuit is generally operated at a higher quiescence current for the input transistors and as a result the frequency response is improved. The gain is reduced by a factor of β. Under most conditions this leads to a more stable amplifier as the gain response rolls off at only 20 db per decade, rather than 40 db in the earlier amplifiers (FIGS. 13-15). Thus this configuration might be best for high frequency operation. This is at the benefit of reduced output current availability. The circuit would also have a lower input impedance but that is generally not a problem with higher speed amplifiers as they are operated with lower impedances. The concern could be the same as with any CFA where there is a problem with non-zero input impedances.

FIG. 17 is a buffer. It uses two proposed devices along with two additional transistors Q₁₇₁ and Q₁₇₂ and current sources I₁₇ to create a buffer able to handle both positive/negative voltages/currents. It is a voltage buffer but can appear to be a current buffer. However it appears, it really is only a voltage buffer with high current gain. It appears when driven by a current, that the output is a function of input current. What really occurs is that the output current develops a voltage across a load and that voltage is reflected back to the input, where the input signal was a current (high impedance). We could better view it as an input current driving a high impedance (the input of the buffer) which will give a voltage. This shows the chameleon like nature of the proposed invention. Otherwise, looking at the circuit, we see that the output is equal to the input voltage plus 600 mV minus 600 mV or on the flip side the output is equal to the input minus 600 mV plus 600 mV. In either case, the output is equal to the input. The only error being offset voltages due to differences in base-emitter voltages when some transistors draw more current that others, mostly of a dynamic nature. This is usually the case with buffers and the reason they are generally used inside a feedback loop with the driving force coming from an operational amplifier. The operational amplifier with feedback will keep any offset near zero. In detail, we see in the circuit that when the input voltage rises, less current is drawn by transistor Q₁ and therefore more current from the current source I₁₇ will drive transistor Q₃ and thus Q₁₇₁, leading to more output current and a rise of the voltage across a load until the voltage across the load is substantially the same as the input. For a negative signal, the action is performed by Q₂, Q₄, and Q₁₇₂. While the above is taking place, that is a signal goes high, the input is also driving current into Q₃ and thus turning the negative side off at the same time the positive side is being turned on and visa versa. Only under extreme cases does one side or the other ever turn completely off. The reason is that the voltage across the bases of Q₁₇₁ and Q₁₇₂ is always equal to approximately 1.2 volts, the voltage generated by the two input base emitter voltages. If one of the output transistors develops a voltage great enough, it can steal off this “bias” voltage and turn off the other output transistor. Note that there is a fault condition that can occur with this circuit. If the output load is “locked” in some manner to a voltage (like zero) and the input voltage goes high (or low) greater than the zener voltage of one the input transistors, the input transistor will fail. The solution is shown included in the schematics of FIGS. 20, 21, and 24. It consists simply of two zeners back to back from the input to the output. The zener diodes must be able to withstand any current that is supplied by the input source. They are not shown in FIG. 17 for simplicity sake and to show the circuit in its simplest form. The voltage gain of the circuit is close to +1. The current gain is simply: β₃*β₁₇₁. The input impedance is β₃*β₁₇₁*R_{L} or β₄*β₁₇₂*R_{L} depending on the polarity of the signal. The ratio of maximum output current to quiescent current is β₃*β₁₇₁ (or β₄*β₁₇₂). This is a very good ratio, indeed. Most buffers have a figure of the order of β, not β², as we have here.

FIG. 18, is just a modification of FIG. 17 to allow the use of FET (MOSFET) transistors Q₇ and Q₈ as detailed in claim 3. This circuit has even higher current gain though it isn't as easy to just write an equation. But a VERY high input impedance. The circuit does either require separate higher voltage supplies to drive the current sources or the output is limited in voltage due to the need for a higher driving voltage to the MOSFETs. The ratio of available output current to quiescent current is much greater than that of FIG. 17.

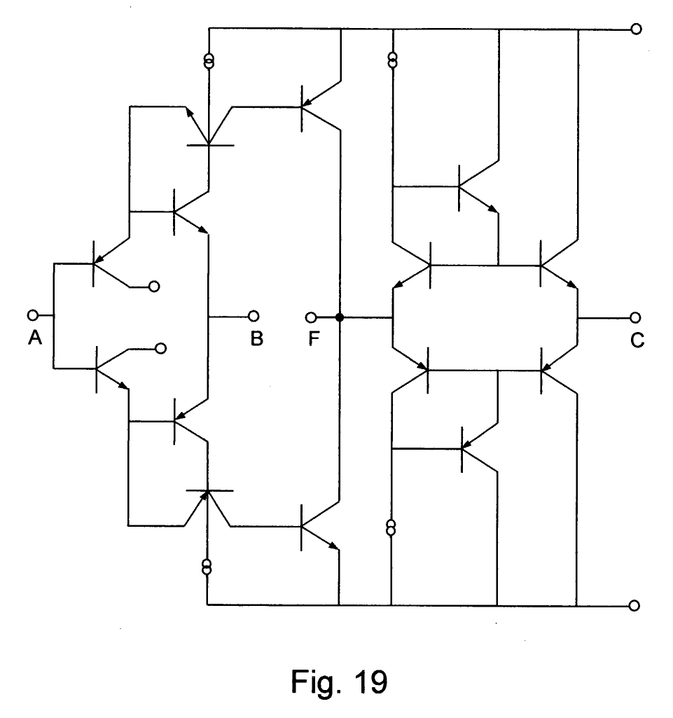

FIG. 19 shows a combination of an amplifier (FIG. 14) and a buffer (FIG. 17) to form a composite amplifier. This amplifier would be suitable for inclusion in an integrated circuit as an operational amplifier. It lends itself well to such an application as there are no resistors in the circuit. The current sources could possibly require resistors but a minimum number as these current sources could be connected and reflected from and thus all stem from actually one constant current source. The amplifier would need to be frequency compensated with the use of a resistor and/or capacitor at the internal connection of the amplifier and buffer, labeled as Point F. Where Z_{f} is the impedance of the external components at point F and is less than the input impedance of the buffer at point F, we see the transresistance of the circuit is β²·Z_{f}. This formula shows that there are many options in configuring the performance of the amplifier. Alternatively, one could use an amplifier with current mirrors such as FIG. 16 for the amplifier portion.

FIG. 20 shows another buffer. Transistors Q₂₀₁ and Q₂₀₂ are used for the input gain stage and Q203 and Q₂₀₄ are used for the output gain stage. It is a modification of the amplifier of FIG. 14 to create a +1 gain amplifier. It has added stability due to the addition of a degeneration resistors R₂₀₁ and R₂₀₂. Most of the parameters of the circuit are similar to those of the other buffers detailed above. The gain is +1. Many of the properties of the circuit could be altered by changing the value of these resistors R₂₀₁ and R₂₀₂. These parameters would include the quiescent current of the output transistors Q₂₀₃ and Q₂₀₄, and the input impedance of the amplifier. This is a very stable configuration. One could remove the resistors by placing the input transistors Q₁ and Q₂ thermally near the output transistors.

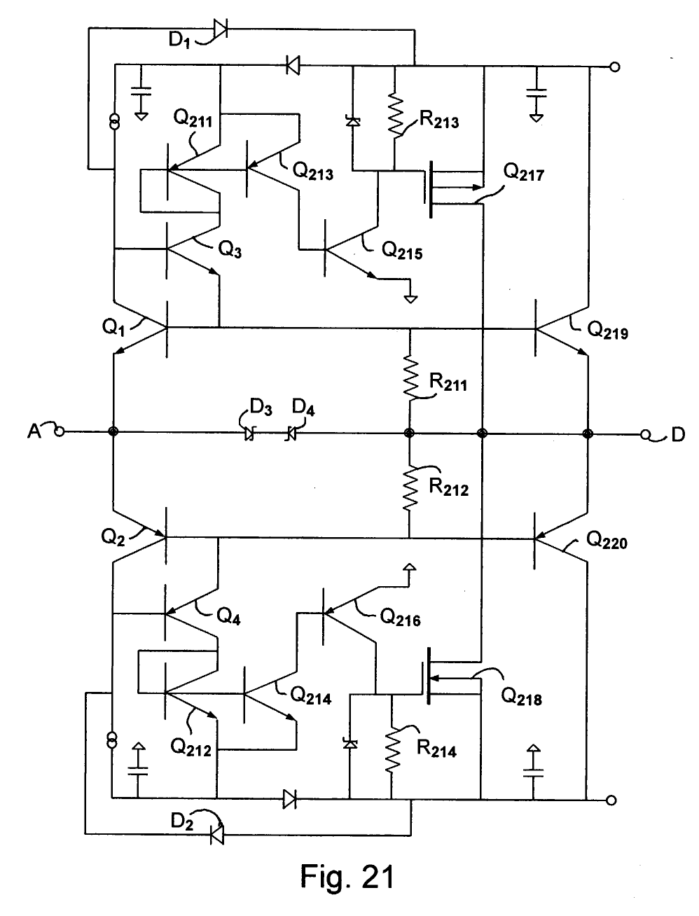

FIG. 21 shows a more complex buffer. It shows how to use MOSFETs to boast the available output current. It is a modification of FIG. 17 with the output transistors now labeled as Q₂₁₉ and Q₂₂₀ and means to take the current from the collectors of Q₃ and Q₄ to drive a boasting circuit which includes MOSFETs Q₂₁₃ and Q₂₁₄. The drive circuitry to the MOSFETs Q₂₁₃ and Q₂₁₄ for the upper and lower halves of the circuit is composed of transistors Q₂₁₁ Q₂₁₃ & Q₂₁₅ and Q₂₁₂, Q₂₁₄ and Q₂₁₆. Resistors R₂₁₃ and R₂₁₄ are used to convert the current to a voltage to drive the MOSFETs. Resistors R₂₁₁ and R₂₁₂ are used to increase the quiescent current of Q₃ and Q₄. The circuit functions by sensing the current drawn by Q₃ in response to a negative input signal and mirroring it to drive a ground connected transistor of Q₂₁₅ that drives the gate of a MOSFET transistor Q₂₁₇ thus supplying current in increasing amounts to the output. Resistors R₂₁₃ and R₂₁₄ are selected so that any voltage developed across them under quiescent conditions will not turn on the MOSFETs. The quiescent current driving R₂₁₃ is β₇*(600 mV/R₂₁₁+2*I₂₁). If R₂₁₃ is made small, the high frequency performance increases because of the gate drive capability. The only price paid is increased thermal dissipation for Q₂₁₅ and Q₂₁₆. One could use current sources for R₂₁₃ and R₂₁₄. Before the MOSFETs start to conduct, the circuit performs exactly like FIG. 17. Note also the addition of the back to back zener diodes D₃ and D₄ to protect Q₁ and Q₃ Anti-saturation diodes D₁ and D₂ prevent the output transistors (Q₂₁₇, Q₂₁₈, Q₂₁₉ and Q₂₂₀) from going into saturation. Whenever the voltage across any of them becomes less than approximately 600 mV, the diodes will conduct and limit the drive current available thus preventing then from being driven any closer to saturation. It is ideal that the supply voltage at the bases of Q₂₁₁ and Q₂₁₃ is higher than that supplying the output transistors so the output can be driven to within 600 mV of the output supply voltage. All this discussion applies to the lower half of the amplifier for the conduction of input signals of a positive polarity that drive the output toward the negative supply. Only different part numbers are applicable.

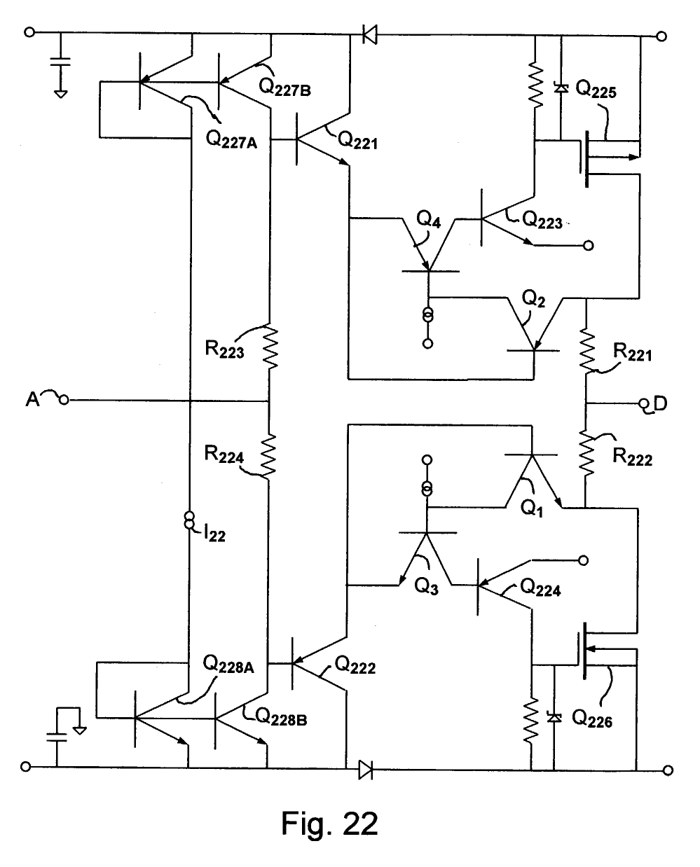

FIG. 22 shows the use of the proposed device to create another buffer. In this circuit, the device is used as a floating amplifier to control the output current of the buffer. There are two embedded amplifiers, one for the positive current and one for the negative current. The quiescent output current is sensed by two output resistors R₂₂₁ and R₂₂₂. The amplifier adjusts the drive on the MOSFETs to match the output current to that requested by the input, which in this case is sensed across another set of resistors R₂₂₃ and R₂₂₄. The two embedded amplifiers are composed of transistors Q₂, Q₄, Q₂₂₁, Q₂₂₃, and Q₂₂₅ for the positive side and transistors Q1, Q₃, Q₂₂₂, Q₂₂₄, and Q₂₂₆ for the negative side. The input resistors R₂₂₃ and R₂₂₄ are driven by a constant current supplied by Q_{227A}, Q_{227B}, Q_{228A}, Q_{228B}, and constant current source I₂₂. Each embedded amplifier is similar to half of FIG. 14. Transistors Q₂ and Q₄ “cascode” a voltage at the emitter of Q₂₂₁ equal to that at the emitter of Q₂ plus approximately 600 mV. A higher voltage at the base of transistor Q₂₂₁ than the emitter of Q₂ will cause Q₄ to drive Q₂₂₃ which in turn drives transistors Q₂₂₅ and raise the output current and voltage until the voltage at the emitter of Q₂ matches that at the base of transistors Q₂₂₁. With increased current output, the voltage across resistor R₂₂₁ will be more than that across R₂₂₃. Therefore the drive voltage to the input of the buffer will have to be higher than the output. This means the voltage gain of the buffer is less than one. This condition is usually handled by including the buffer inside a feedback loop with an operational amplifier. The same fault condition could apply here as in earlier buffers when the input becomes greater than the output by more than the zener breakdown voltage of Q₂ and the same solution handles it, i.e. back to back zener diodes from input to output. The current could be limited by resistors R₂₂₃ and R₂₂₄ and the impedance of the source but it is the voltage that kills the transistor and not current in this mode. These zener diodes are not shown in FIG. 22. The amount of drive current needed from the constant current sources is very small as that current is multiplied by Q₂₂₁ and Q₂₂₃ to drive Q₂₂₅. All this discussion applies equally to the negative side of the buffer, only with different components and polarities.

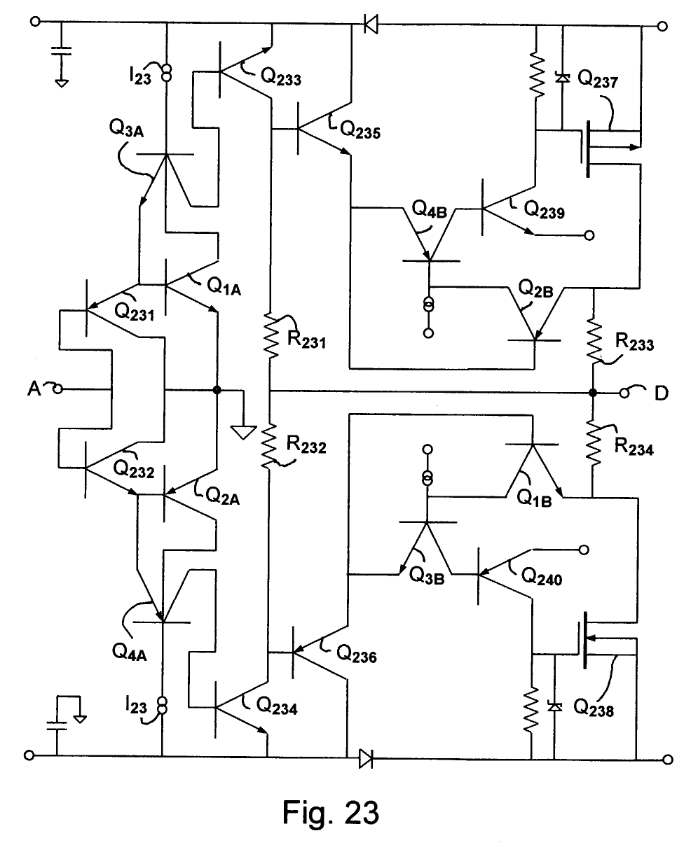

FIG. 23 shows another amplifier and buffer circuit that is built around the use of the proposed device. In fact there are 4 devices used in FIG. 23. They are noted as A and B added to the subscripts for the transistors, i.e. Q_{1A}, Q_{1B}, Q_{2A}, Q_{2B}, Q_{3A}, Q_{3B}, Q_{4A}, and Q_{4B}, to make it easier to spot where the devices are located. This circuit uses 2 of the devices to create the amplifier front end. Transistors Q₂₃₁ and Q₂₃₂ are used for the input gain stages and Q₂₃₃ and Q₂₃₄ are used for the output gain stages of the amplifier portions of the circuit. Quiescent currents are set by current sources I₂₃. In this case, the output current of the amplifier portion is very tightly controlled. Transistors Q₂₃₅ and Q₂₃₆ are used for the input gain stages and Q₂₃₉ and Q₂₄₀ are used for the output or driver gain stages of the output portions of the amplifier. These output amplifiers drive transistors Q₂₃₇ and Q₂₃₉ to complete their portions of the circuit. The output amplifier portions will operate to keep the voltage dropped across R₂₃₁ and R₂₃₂ duplicated exactly across R₂₃₃ and R₂₃₄. The output current is a multiple of the current through R₂₃₁ and R₂₃₂. Therefore the ratio of available output current to quiescent current is the same as that of the amplifier portion. This ratio is generally limited to the order of β. If the output resistors R₂₃₃ and R₂₃₄ are 0.1 Ohms and the “driving” resistors are 100 Ohms and are driven with 50 μA then there is 5 mV across both sets. The quiescent output stage current is then 50 mA. A drive of 10 mA through R₂₃₃ would produce 10 Amps output current. The amplifier buffer combination has a roll over of 40 db per octave and so will need some compensation to be stable. There are several places a capacitor could be placed including a) output to ground b) from base to collector of transistors Q₂₃₃ and Q₂₃₄ c) across R₂₃₁ and R₂₃₂ d) across the feedback resistor. Another approach would be to enhance the high frequency response of the amplifier to keep the loop gain from reaching zero “too” early. This could be accomplished with capacitors across resistors R₂₃₃ and R₂₃₄. With the high output power capability from the use of MOSFETs Q₂₃₇ and Q₂₃₈, the exact control of these MOSFETs, and the high performance amplifier front end, this is a very high quality circuit. It is stable, easy to design for, requires no matched parts to function and can be customized to meet almost any need. A quick look at offset is useful here. The input offset of the amplifier is that current needed to produce a zero output current or voltage. In this case, that would substantially met when the voltage across R₂₃₁ and R₂₃₂ are equal. The upper current and lower current of the amplifier portion of the circuit are equal. Thus the input (offset) current would be =(1/(β₂₃₁*β₂₃₃)−1/(β₂₃₂*β₂₃₄))β₂₃₄*I₂₃) where β₂₃₄ is assumed larger than β₂₃₃. Worse case assume that I₂₃₂*β₂₃₄ is much larger than β₂₃₁*β₂₃₃ then input current will be (β₂₃₄/(β₂₃₁*β₂₃₃))*I₂₃. If β₂₃₄=2*β₂₃₃ then Input current will be 2*I₂₃/β₂₃₁. A possible value of I₂₃ is 1 μA. A value of I₂₃₁=50 would give an input current of 40 nAmps. If all the input current were supplied by an input resistor Rᵢₙ (as shown in FIG. 31) of 500 Ohms, then the output offset would be 2 μV. If all the current were supplied by a feedback resistor R_{f} (as shown in FIG. 31) of 5000 Ohms, then the output offset voltage would be 20 μV, independent of the closed loop gain of the amplifier. These figures could be improved by proper design of an integrated circuit. When used for a DC Amplifier measuring small voltage across very low impedances, all the input current would come through Rᵢₙ, which could be made even smaller than 500 Ohms. A possible value could be 10 Ohms. This would give an output offset voltage of 0.4 μV. When used with an R_{f} of 1000 Ohms, the amplifier would have a gain of 100. The output offset reflected back to the input would appear as 4 nvolts. Layout and physical aspects of the circuit would take priority in keeping to offset low.

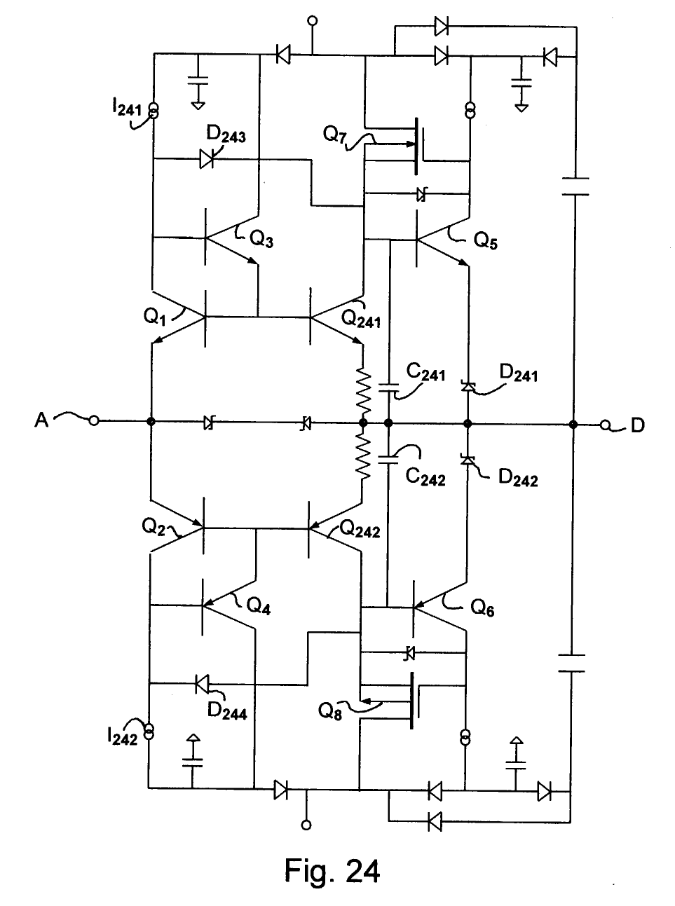

FIG. 24 shows the use of the device to create a high performance buffer. There are 4 uses of the device in this buffer. A pair to create the buffer itself and another pair to create the floating buffered power supply for the output devices. The main part of the buffer consists of transistors Q₁-Q₄, Q₂₄₁ and Q₂₄₂ and current sources I₂₄. The output transistors Q₂₄₁ and Q₂₄₂ are cascoded by the third and four usages of the device. Q₅ & Q₇ and Q₆ & Q₈ produce an exact low voltage across the output transistors. A voltage of 1.8 volts might is appropriate. Maybe higher might be needed to give greater range and holdup. This voltage is determined by zener diodes D₂₄₁ and D₂₄₂. The voltage seen by the output transistors at their collectors then would be + and − that zener voltage plus approxiamtely 600 mV for the V_{be} voltages of transistors Q₅ and Q₆. Capacitors C₂₄₁ and C₂₄₂ are hold up units. They hold and supply most of the power used by the output transistors. Even when a MOSFET might be turned off because there is no headroom for it to operate, there would still be power for the output transistors. As long as the current sources I₂₄₁ and I₂₄₂ have enough voltage headroom of their own to drive the output transistors, the output of the buffer could go higher than the main power supply voltage. The schematic shows bootstrapping to give enough voltage to drive the MOSFETs but that same bootstrapping could be used to supply the other current sources. Note also that the unit has anti-saturation diodes D₂₄₃ and D₂₄₄. Whenever the voltage across Q₂₄₁ or Q₂₄₂becomes less than about 600 mV the anti-saturation diodes start to conduct and prevent any more drive thus preventing the output transistors from going into saturation. This is very important when using high gain amplifiers as they tend to go into saturation very hard because of the intention of the amplifier to get its way and move that voltage even higher when there is no supply voltage left to do so. Transistors when driven in this manner can stay in saturation for a long time. A very serious source of distortion.

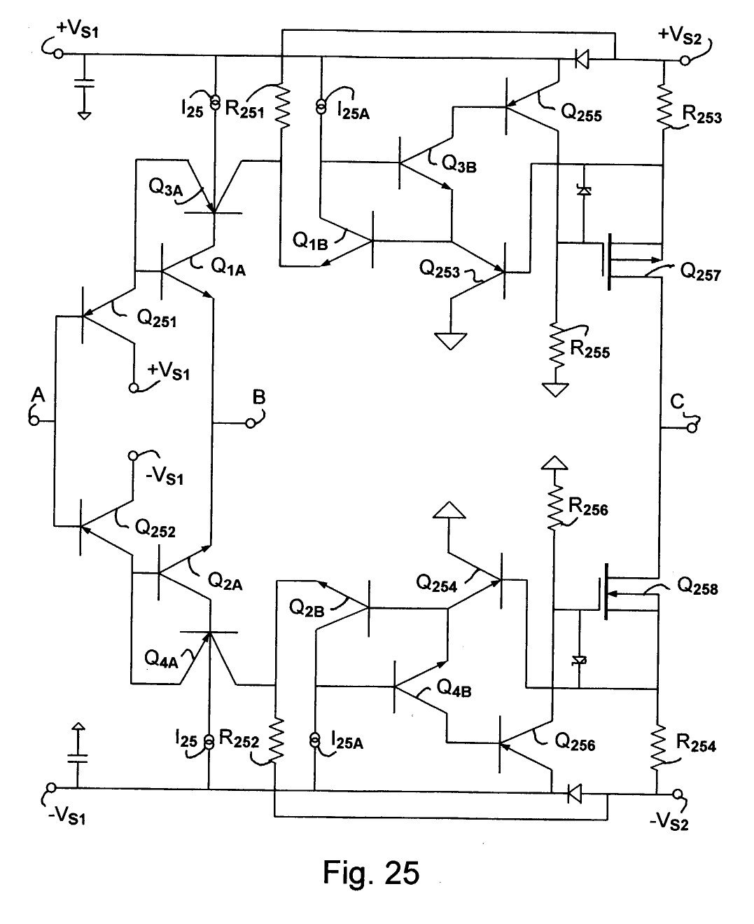

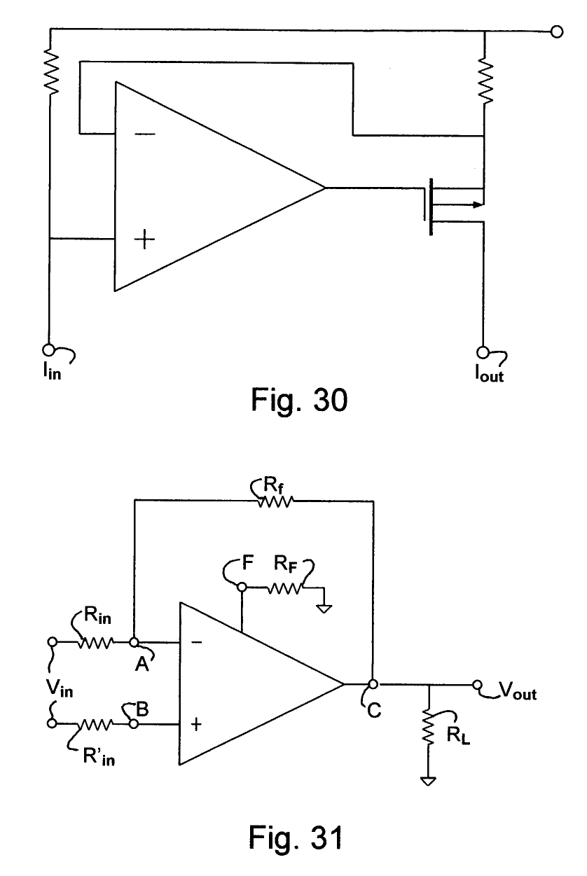

FIG. 25 uses four of the proposed devices to create a very exacting amplifier. The amplifier has a front end composed of two proposed devices configured similar to FIG. 14 with input gain stage transistors Q₂₅₁ and Q₂₅₂ without the second stage current gain transistors. Transistors Q_{1A}, Q_{2A}, Q_{3A}, and Q_{4A} are the transistors of the front end. The current input after being amplified and passing through the proposed devices drives resistors R₂₅₁ and R₂₅₂. The voltage across these resistors R₂₅₁ and R₂₅₂ is duplicated across resistors R₂₅₃ and R₂₅₄ by the embedded amplifiers composed of Q_{1B}, Q_{3B}, Q₂₅₃, Q₂₅₅, and Q₂₅₇ along with R₂₅₃ & R₂₅₅ and current source I_{25A} for the upper half and by Q_{2B}, Q_{4B}, Q₂₅₄, Q₂₅₆, and Q₂₅₈ along with R₂₅₄ & R₂₅₆ and current source I_{25A} for the lower half. See FIG. 30 for a simplified circuit that shows a positive rail voltage mirror. That is basically what is being done here. If the drive current from Q₂₅₁ increases the current across R₂₅₁, Q_{1B} will draw more current from current source I_{25A} and thus turn Q_{3B} off lowering the drive to Q₂₅₅ and thus across R₂₅₅ and turning MOSFET transistor Q₂₅₇ further on until the voltage across R₂₅₃ increases to match that across R₂₅₁. This increased current from Q₂₅₁ in response to a negative current/voltage will cause the output current to increase thus increasing the output voltage. A positive input will cause the lower portion of the circuit to draw current causing the output to go low. It is clear then that A is an inverting input and suitable for negative feedback. The quiescent current of the transistors in the amplifier front-end are all the same and equal to the current from the current sources I₂₅. This current also goes through resistors R₂₅₁ and R₂₅₂. As an example, assume R₂₅₁ (& R₂₅₂) are equal to 100 Ohms and that I₂₅ is set to 50 μA giving a voltage of 5 mV. This same 5 mV across R₂₅₃ (and R₂₅₄), which are equal to 0.1 Ohms, causes 50 mA quiescent current to flow in Q₂₅₇ and Q₂₅₈. If we use high gain transistors for Q₂₅₁, Q₂₅₂, Q_{3A}, and Q_{4A} with a beta of 200, then at maximum drive we get 10 mA current through R₂₅₁ (or R₂₅₂) and 1 Volt. The 1 Volt in turn causes 10 Amps to flow through R₂₅₃ and Q₂₅₇ (or R₂₅₄ and Q₂₅₈) into an output load. We can figure the voltage gain of the device as follows:
Vₒᵤₜ=Iₒᵤₜ*R_{L}=β₂₅₁*(R₂₅₁/R₂₅₃)*Iᵢₙ*R_{L}==β₂₅₁*(R₂₅₁/R₂₅₃)*R_{L}*Vᵢₙ/Rᵢₙ)
Aᵥₒₗ=Vₒᵤₜ/Vᵢₙ=β₂₅₁*(R₂₅₁/R₂₅₃)*(R_{L}/Rᵢₙ)
Loop Gain=β₂₅₁*(R₂₅₁/R₂₅₃)*(R_{L}/Rᵢₙ)*(Rᵢₙ/R_{f})=β₂₅₁*(R₂₅₁/R₂₅₃)*(R_{L}/R_{f})
Transresistance=β₂₅₁*(R₂₅₁/R₂₅₃)*R_{L}

We see from the loop gain equation that the amplifier has only one dominant pole and therefore stable. If we selected resistors such that (R₂₅₁/R₂₅₃)*(R_{L}/R_{f})=1, then the Loop Gain would =β₂₅₁. We see that the zero intercept would not come until β₂₅₁=1, which is F_{T} for that transistor. This is a very high cutoff point. This is especially high for an audio amplifier, which normally extends maybe to 1 MHz but rarely higher. In fact, an input filter is generally used to keep these kinds of frequencies from reaching the amplifier. There are several ways to compensate the amplifier for frequency stability or to reduce the frequency response. One could add capacitors across R₂₅₁ (and R₂₅₂) or across the load R_{L}. One could use lower frequency input transistors. One could extend the zero loop gain point by adding a capacitor across R₂₅₃ (and R₂₅₄) or across the feedback resistor R_{f} (at the expense of closed loop frequency response). A combination of capacitors could be used to tailor the response. Some things need to be noted about the circuit. A higher supply voltage is needed for I_{25A} and Q₂₅₅ (and Q₂₅₆) to allow the transistors to sense a voltage that is so near the output power supply rails. The ratio of available output current to quiescent current is limited to the beta of transistors Q_{3A} and Q_{4A}. A fault mode that is possible in some of the circuits detailed in this application does not apply to this one as the current drive from the input transistors is not enough to drive R₂₅₁ (or R₂₅₂) to a voltage greater than the zener voltage of the base-emitter of Q₂₅₃ (or Q₂₅₄). A look at the input current (offset) of the circuit, using R_{f} of 100,000 and a 20% match of β₂₅₂ and β₂₅₁, gives us the following:
I_{offset}=I₂₅/β₂₅₂−I₂₅/β₂₅₁=0.2*I₂₅/β₂₅₁=0.2*50 μA/100=100 nA
V_{offset}=R_{f}*I_{offset}=100,000*100 nA=10 mV at the output worse case

For a large high current output amplifier driving 8 Ohms, this is just fine. 10 mA*80 mV=800 μWatts.

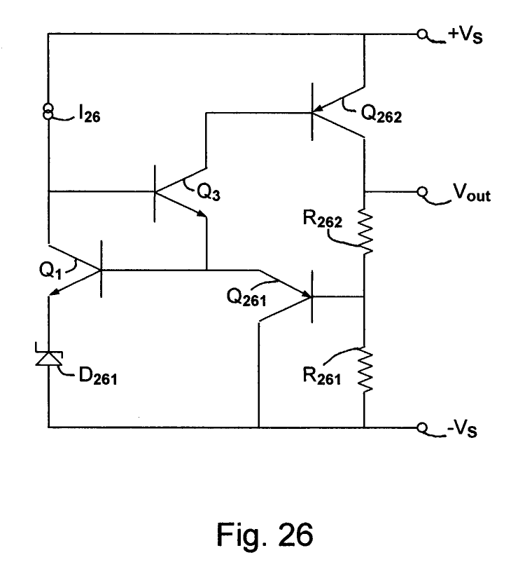

FIG. 26 shows the use of the device to create a voltage regulator. It is similar to the amplifiers detailed earlier. Transistors Q₁, Q₃, Q₂₆₁, and Q₂₆₂ along with current source I₂₆ and gain setting resistors R₂₆₁ and R₂₆₂ compose the amplifier. The zener D₂₆₁ supplies a reference voltage but could replace with any kind of voltage reference such as band-gap or sub 1 volt references. Examples of sub 1 volt references are detailed in Monochip Application Note APN-25 by Interdesign—A Feranti Company titled Low Voltage Bipolar Circuits by Derek Brey. They show stable reference voltages below 200 mV. With no load, the quiescent current of all parts of the circuit are the same and equal to I₂₆. Therefore R₂₆₁ must be less than the zener voltage of D₂₆₁ divided by I₂₆ for stable operation. Maximum current output is β₃*β₂₆₂*I₂₆. The quiescent current is 2*I₂₆. The ratio is β₃*β₂₆₂/2. This is a good measure of a regulator. The regulator can regulate down to the reference voltage. The circuit does require some headroom as configured. The input supply voltage must be greater than the reference voltage by 1.2 to 1.6 volts depending on output current demands. The circuit can regulate to 600 mVolts using a diode as the reference. Below this one would have to split the voltage from a diode reference or use a sub 1 volt reference to get a smaller reference voltage at the emitter of Q₁). Diodes aren't very good references due to temperature drift and tolerances. But for many applications they can work just fine, particularly at very low voltages. The circuit can convert any input voltage greater than about 2 volts to any of 0.6, 1.2 or 1.8 volts very handily.

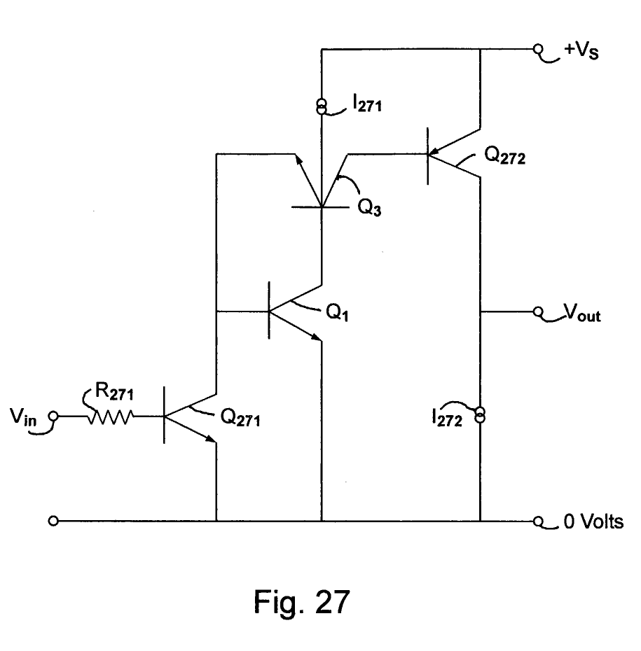

FIG. 27 is the first digital circuit of this application. It is an OR circuit and uses the proposed device (transistors Q₁ and Q₃) to cascode a common emitter input transistor Q₂₇₁. With no input the output current from transistor Q₂₇₂ is β₂₇₂/β₁*I₂₇₁. If I₂₇₂ is twice the current of I₂₇₁, then the output should be low. If any input is high, then the output current will at a maximum =β₃*β₂₇₂*I₂₇₁. This ratio is =β₁*β₃. A very good measure of fan out for a digital circuit. The supply voltage appears to need to be about 1.2 volts to function. The voltages are distributed a little differently whether the circuit is on or off but the voltage needed is about the same. A limit must be placed on the input current. A choice is to limit the input current to that of I₂₇₁, the largest usable amount of current that can increase the output current. With the small supply voltages being used, a volt drop should be plenty. Rᵢₙₚᵤₜ=1/I₂₇₁=1/10 μA=100 K. A better solution in an integrated circuit can be devised and save the space required by such a large resistor. This circuit is all based on current steering and has the potential to be very fast. One can vary the supply voltage and currents used internal to get the kind of performance desired. The circuit is suitable to drive large amount of current into a load. If I₂₇₁ is set to 1 mA then a drive of 1 mA into the circuit will produces many Amperes of current out. And of course it could be operated from a much higher supply so that output could be great indeed.

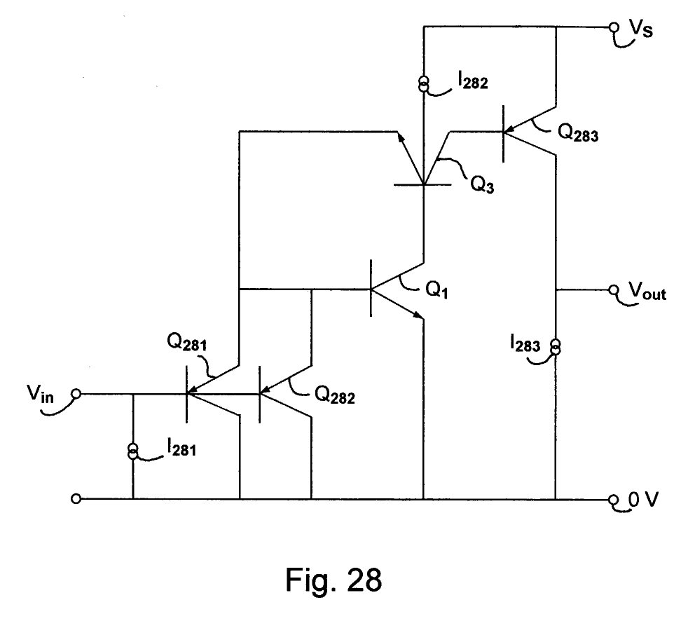

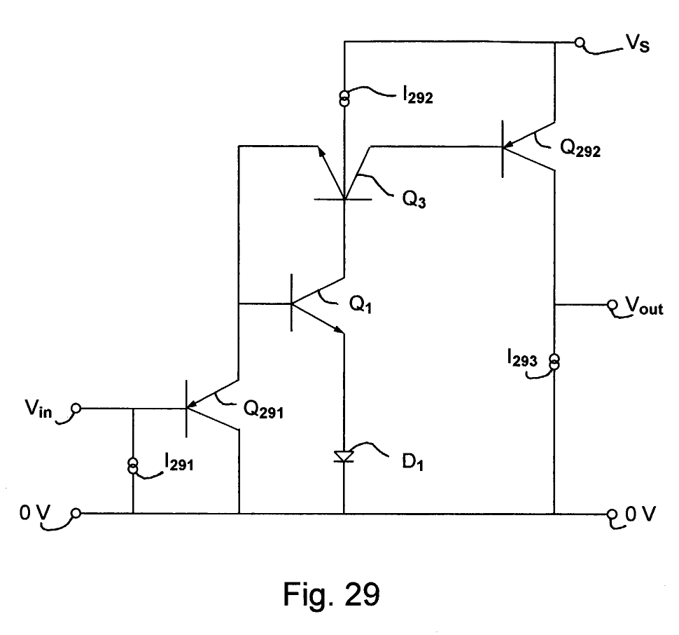

FIGS. 28 and 29 are very similar. They are both NOR gates. The difference is that FIG. 28 uses dual input transistors Q₂₈₁ and Q₂₈₂ in parallel to reduce the base emitter voltage to less than that of Q₁, whereas FIG. 29 inserts a diode D₁ between the emitter of Q₁ and ground to make sure the voltage at the base of Q₁ is higher than the base-emitter voltage of Q₂₉₁. Both cases desire that Q₂₉₁ (or Q₂₈₁ and Q₂₈₂) will be fully on under no input conditions. In both circuits, a high input voltage (current) will saturation the current source I₂₈₁ (or I₂₉₁) and turn Q₂₉₁ (or Q₂₈₁ and Q₂₈₂) off. When Q₂₉₁ (or Q₂₈₁ and Q₂₈₂) turns off, the circuit reverts to a low current condition. The amount of current that will then flow from the output transistor Q₂₈₂ (or Q₂₉₃) is β₂₈₂/β₃*β₂₉₂ (or β₂₉₃/β₃* I₂₉₂). If I₂₈₃ (or I₂₉₃) is twice I₂₈₂ (or I₂₉₂) then the output will go low. One does not have to limit the input current, as the input will only draw I₂₈₁ (or I₂₉₁). The available output current for FIG. 29 is β₃*β₂₉₂*I₂₉₂ or β₂₉₁*β₂₉₂ *I₂₉₁, whichever is lower. The available output current for FIG. 28 is β₃*β₂₈₃*I₂₈₂ or β₂₈₁*β₂₈₃*I₂₈₁, whichever is lower. The ratio of available output current to quiescent current is of the order of β². This is a high fan-out for a digital circuit. It could even be used to drive fairly large loads. The circuits function on current steering and thus are very fast. The circuit in FIG. 29 requires 600 mV more supply voltage than the circuit in FIG. 28. FIG. 28 might be able to operate from as low as 1.2 volts.

From the forgoing, it should be clear that the present invention may be embodied in forms other than those described above. The above-described examples are therefore to be considered in all respects illustrative and not restrictive or limiting, the scope of the invention being indicated by the appended claims rather than the foregoing. All changes that come within the meaning and scope of the claims are intended to be embraced therein

### Advantages

The advantages that can be gained by using the proposed device fit in the following:
1) Low Voltage Operation
   Many of the amplifiers/buffers can operate at voltages less than +−1.5 volts.
2) Low Offset and Noise
   See discussion under FIGS. 23 and 25.
3) Extended Frequency Response
   As many of the amplifiers operate as CFAs, the frequency response is very good. See discussion under 13 and 25.
4) Configurable for Low Power to High Power Operation
   FIG. 16 could be configured with +−1.5 volt supply and quiescent current drain of 30 μA. Total power of 90 μW. Very good performance. Some of the designs could be configured for very large power output. Thousand of Watts output could be produced and still have stability in the internal circuit currents. See 9 below.
5) Simplicity
   Circuit designs are simpler than previous circuits. Complete operational amplifiers can be built around 8 transistors and 2 current sources (FIG. 15). High current gain buffers can be built with 6 transistors and 2 current sources (FIGS. 17 & 18).
6) Stability—Internal Currents
   Quiescent currents are exactly controlled. Even for MOSFETs.
7) No Saturation
   Inherent in the use of the device is that new configurations prevent transistors from going into saturation. FIG. 13 only the output transistors can go into saturation. FIG. 17 only the current sources are a concern. Figures for the more complex buffer circuits lend themselves very easily to the addition of an anti-saturation diode (FIGS. 21 and 24).
8) Lower Distortion—No CrossOver Distortion
   Because of the control of quiescent currents and the inherent way the invention works, only under extreme conditions do any transistors even get turned off. There is a passing of current going on and no dead spaces that a voltage must pass through to elicit a response. In FIGS. 13 and 17, even the smallest amount of input current/voltage will produce an output change.
9) High ratio of output current to quiescent current
   Previous designs generally must settle for a ratio of available output current to quiescent current of β. In many of the circuits detailed in this patent, the ratio is β². Those circuits that use FIGS. 8c and 8d, i.e. use MOSFETs, the ratio is much higher (FIGS. 15 and 18).

1. A analog electronic device comprising:
four terminals and means such that
said terminal 1 accepts a current of predetermined direction;
said terminal 2 is receptive to an input signal;
said terminal 3 causes a current to flow;
said terminal 4 has means to concurrently produce an output voltage and current in response to the voltage and current at said terminal 2 and to sense said voltage and current at said terminal 4 and to adjust said voltage and current at said terminal 2 and said current at said terminal 3; and
whereby said device can be used to create amplifiers, cascoding devices, buffers, regulators, and digital circuits with new topologies.

2. A four terminal analog electronic device comprising:
two bipolar transistors of like type or conductivity;
said terminal 1 is the connection of the base of said second transistor and the collector of said first transistor;
said terminal 2 is the emitter of said first transistor;
said terminal 3 is the collector of said second transistor;
said terminal 4 is the connection of the base of said first transistor and the emitter of said second transistor, and;
thereby
said terminal 1 accepts a current of predetermined direction;
said terminal 2 is receptive to an input signal;
said terminal 3 causes a current to flow in a predetermined direction;
said terminal 4 concurrently produces an output voltage and current in response to the voltage and current at said terminal 2 and senses said voltage and current at said terminal 4 and to adjusts said voltage and current at said terminal 2 and said current at said terminal 3; and
whereby said device can be used to create amplifiers, cascading devices, buffers, regulators, and digital circuits with new topologies.

3. A four terminal analog electronic device comprising:
a bipolar transistor and a FET transistor of like type or conductivity,
said terminal 1 is the connection of the gate of said FET transistor and the collector of said bipolar transistor;
said terminal 2 is the emitter of said bipolar transistor;
said terminal 3 is the drain of said FET transistor;
said terminal 4 is the connection of the base of said bipolar transistor and the source of said FET transistor, and,
thereby
said terminal 1 accepts a current of predetermined direction;
said terminal 2 is receptive to an input signal;
said terminal 3 causes a current to flow in a predetermined direction;
said terminal 4 concurrently produces an output voltage and current in response to the voltage and current at said terminal 2 and senses said voltage and current at said terminal 4 and to adjusts said voltage and current at said terminal 2 and said current at said terminal 3; and
whereby said device can be used to create amplifiers, cascoding devices, buffers, regulators, and digital circuits with new topologies.

4. The device as set forth in claim 1 used as a cascoding device wherein:
said terminal 1 is supplied with a predetermined current,
said terminal 2 is referenced by a predetermined voltage,
said terminal 3 causes a current to flow from a predetermined supply voltage by way of a sensing device, where said sensing device would include, but not limited to, a resistor, base-emitter junction, and current mirror and,
said terminal 4 supplies an object gain transistor with a voltage that is substantially unchanging and any current drawn by said gain transistor is substantially the same as that caused to be drawn by said terminal 3;
whereby as the current drawn by said terminal 3 is substantially the same as the current drawn from said terminal 4 by said gain transistor, said current drawn by said terminal 3 can be used in a similar manner to that of a prior art cascode circuit i.e., to produce a voltage across an impedance, to drive a transistor or to drive a current mirror.

5. The device as set forth in claim 4 wherein:
said gain transistor is a more complicated circuit such as an operational amplifier;
whereby a low voltage integrated operational amplifier can be use with a higher supply voltages and is buffered from those higher voltages by the use a plurality of cascode circuits as taught in claim 4.

6. The device as set forth in claim 1 used to create an amplifier stage wherein:
said device is used to buffer a first current gain stage and drive a second current gain stage;
said terminal 1 is supplied with a predetermined current,
said terminal 2 is referenced by a voltage,
said terminal 3 is supplied with a predetermined supply voltage by way of the base-emitter junction of said second current gain stage and causes a varying current to flow equal to that drawn by said first current gain stage transistor through said base-emitter junction of said second current gain stage,
said terminal 4 supplies said first object gain transistor with a voltage that is substantially unchanging,
collector of said first current gain stage is connected to a supply voltage of opposite polarity to that supplying terminals 2 and 3 which could be ground, and
collector of said second gain stage is the output of the circuit;
whereby the input current to said first current gain stage produces a current from said second current gain stage equal to beta of said first current gain stage times beta of said second current gain stage times said input current and said output current can drive a load impedance to produce a voltage.

7. The amplifier stage as set forth in claim 6 used to create an amplifier wherein:
two symmetrical stages of claim 6 of opposing polarity are combined;
where said inputs are connected together forming a composite input,
said outputs are connected together forming a composite output and,
said second terminals of said respective symmetrical stages are connected and act as a reference point for the circuit;
whereby a current of either polarity input into said composite input produces a current at said composite output equals to minus beta of said first current gain stage times beta of said second current gain stage where current is amplified by one of said symmetrical stages depending of the polarity of the input current, and;
whereby the amplifier can be used with negative feedback due to the lack of significant offset voltage.

8. The amplifier of claim 7 wherein said reference point is connected to ground.

9. The amplifier of claim 7 wherein said reference point is used functionally as a non-inverting input;
whereby said non-inverting input signal causes amplifier to operate differently depending on impedance of signal;
whereby a current supplied to said non-inverting input produces a current at the output equal to beta of said second transistor times beta of said second current gain stage times input current difference;
whereby if said inputs are driven by voltages instead of currents then output current will be a function of the difference of input voltages.

10. The amplifier of claim 7 comprising:
four (4) NPN transistors, four (4) PNP transistors and two (2) current sources connected as follows:
the base of first PNP transistor is connected to the base of first NPN transistor and is the input of the amplifier;
the collectors of said first NPN and said first PNP transistors are connected to predetermined supply voltages which could include ground;
the emitter of said first PNP transistor is connected to the base of second NPN transistor and to the emitter of third NPN transistor;
the emitter of said first NPN transistor is connected to the base of second PNP transistor and to the emitter of third PNP transistor;
the base of said third NPN transistor is connected to the collector of said second NPN transistor and to one end of a first current source;
the base of said third PNP transistor is connected to the collector of said second PNP transistor and to one end of a second current source;
the emitters of said second NPN and said second PNP transistor are connected together and driven by a signal;
the collector of said third NPN transistor is connected to the base of fourth PNP transistor;
the collector of said third PNP transistor is connected to the base of fourth NPN transistor;
the emitters of said fourth NPN and said fourth PNP transistors are connected to predetermined supply voltages and,
the collectors of said fourth NPN transistor and said fourth PNP transistors are connected together and constitute the output of the invention;
whereby a current of either polarity input into said composite input produces a current at said composite output equals to minus beta of said first current gain stage times beta of said second current gain stage times the input current where the input current is amplified by one of said symmetrical stages depending of the polarity of the input current;
whereby if said input is driven by voltage instead of current then output current will be a function of the difference of said input voltage and said signal voltage at the connection of emitters of said second NPN transistor and said second PNP transistor.

11. The device as set forth in claim 1 used to create a buffer amplifier.

12 The buffer amplifier of claim 11 comprising:
two (2) devices of claim 1 of opposite polarity along with two bipolar transistors and two current sources wherein:
said terminal 2 of each said device is connected to the terminal 2 of other said device and said connection is functionally the input of said buffer;
said terminal 1 of each said device is connected via a current source to a predetermined supply voltage of the correct polarity;
said terminal 3 of each said device is connected to a predetermined supply voltage of the correct polarity;
said terminal 4 of each said device is connected to the base of one of said bipolar transistors of same polarity as that of said device respectively;
collectors of each said bipolar transistor are connected to a predetermined supply voltage of the proper polarity and the emitters of each of said bipolar transistors are connected together and constitutes the output of said buffer amplifier;
whereby an input of a voltage at a low impedance will a substantially equal output voltage, differing only by a varying offset due to the differences of base-emitter voltages of said transistors under varying conditions and;
whereby an input of a current at a high impedance will produce an output current equal to β² times said input current.

13. The buffer amplifier of claim 11 comprising:
three (3) PNP transistors, three (3) NPN transistors and two (2) current sources;
the emitters of first NPN transistor and first PNP transistor are connected together and constitute the input;
the collector of said first NPN transistor is connected to the base of the second NPN transistor and to one end of a first current source where opposite end is connected to a predetermined positive supply voltage;
the base of said first NPN transistor is connected to the emitter of said second NPN transistor and the base of third NPN transistor;
the collectors of said second NPN transistor and said third NPN transistor are connected to a predetermined positive supply voltage;
the collector of said first PNP transistor is connected to the base of the second PNP transistor and to one end of a second current source where opposite end is connected to a predetermined negative supply voltage;
the base of said first PNP transistor is connected to the emitter of said second PNP transistor and the base of third PNP transistor;
the collectors of said second PNP transistor and said third PNP transistor are connected to a predetermined positive supply voltage;
the emitters of said third NPN transistor and said third PNP transistor are connected together and constitute the output;
whereby an input of a voltage at a low impedance will produce a substantially equal output voltage, differing only by a varying offset due to the differences of base-emitter voltages of said transistors under varying conditions and;
whereby an input of a current at a high impedance will produce an output current equal to β² times said input current only limited by the drive current of the current sources.

14. The buffer amplifier of claim 11 comprising:
two (2) PNP transistors, two (2) NPN transistors, one (1) n-channel MOSFET, one (1) p-channel MOSFET and two (2) current sources;
the emitters of first NPN transistor and first PNP transistor are connected together and constitute the input;
the collector of said first NPN transistor is connected to the gate of the first n-channel MOSFET transistor and to one end of a first current source where opposite end is connected to a predetermined positive supply voltage;
the base of said first NPN transistor is connected to the source of said first n-channel MOSFET transistor and the base of second NPN transistor;
the drain of said first n-channel MOSFET transistor and the collector of said second NPN transistor are connected to a predetermined positive supply voltage;
the collector of said first PNP transistor is connected to the base of the first p-channel MOSFET transistor and to one end of a current source where opposite end is connected to a predetermined negative supply voltage;
the base of said first PNP transistor is connected to the source of said first p-channel MOSFET transistor and the base of second PNP transistor;
the drain of said first p-channel MOSFET transistor and the collector of said second PNP transistor are connected to a predetermined positive supply voltage;
the emitters of said second NPN transistor and said second PNP transistor are connected together and constitute the output;
whereby an input of a voltage at a low impedance will produce a substantially equal output voltage, differing only by a varying offset due to the differences of base-emitter voltages of said transistors under varying conditions and;
whereby an input of a current at a high impedance will produce an output current greater than that seen using bipolar transistors in place of the MOSFET transistors.

15. The device as set forth in claim 1 used to create a voltage regulator.

16. The device as set forth in claim 1 used to create a digital circuit
wherein said digital circuit can include OR gates and NOR gates.

17. The OR gate digital circuit as set forth in claim 16 comprising:
three (3) NPN transistors, one (1) PNP transistors and two (2) current sources connected as follows:
the collector of a first NPN transistor and the base of a second NPN transistor are connected to the emitter of a third NPN transistor;
the collector of said second NPN transistor and the base of said third NPN transistor are connected to one end of a first current course where opposite end of said first current source is connected to a predetermined positive supply voltage;
the emitters of said first NPN transistor and said second NPN transistor are connected to a reference voltage which includes ground;
the collector of said third NPN transistor is connected to the base of a first PNP transistor;
the emitter of said first PNP transistor is connected to a predetermined positive supply voltage;
the collector of said first PNP transistor is connected to one end of a second current source where the opposite end of said second current source is connected to said reference voltage and this connection constitutes the output of the circuit; and
the base of said first NPN transistor is the input of the circuit;
whereby the absence of an input signal causes the output to go to a low voltage;
whereby an input signal below 500 mV causes the output to go to a low voltage;
whereby the presence of a high input signal causes the output to saturate to the positive supply voltage with a current capability of beta of said third NPN transistor times beta of said first PNP transistor times the current supplied by said first current source,
whereby the ratio of output current to required input current is basically equal to the beta of said first NPN transistor times the beta of said first PNP transistor where such figure called fan-out is on the order of 10,000;
whereby said digital circuit can operate on a voltage below 1.5 volts.

18. The NOR gate digital circuit as set forth in claim 16 comprising:
two (2) NPN transistors, two (2) PNP transistors, one (1) diode and three (3) current sources connected as follows:
the base of a first PNP transistor is connected to one end of a first current source and this connection is the input of the digital circuit, where opposite end of said first current source is connected to a reference voltage which can include ground;
the collector of said first PNP transistor is connected to said reference voltage;
the emitter of said first PNP transistor is connected to the base of first NPN transistor and to the emitter of second NPN transistor;
the emitter of said first NPN transistor is connected to a diode where opposite end of diode is connected to said reference voltage;
the base of said second NPN transistor is connected to the collector of said first NPN transistor and to one end of a second current source, where said second current source is connected to a predetermined positive supply voltage;
the base of said second PNP transistor is connected to the collector of said second NPN transistor;
the emitter of said second PNP transistors is connected to a predetermined positive supply voltages and,
the collector of said second PNP transistors is connected to is the output of the device and is further connected to a third current source where opposite end of said third current source is connected to said reference voltage;
whereby the absence of an input signal causes the output to saturate to the positive supply voltage with a current capability of beta of said first PNP transistor times beta of said second PNP transistor times the current drawn by said first current source;
whereby the presence of a high input signal the output goes into a off state where there is some current being output which can swamped by the said third current source as such output current is of the order of the current being supplied by said second current source;
whereby the ratio of output current to required input current is basically equal to the beat of said first PNP transistor times the beta of said second PNP transistor and such figure called fan-out is on the order of 10,000;
whereby said digital circuit can operate on a voltage below 2 volts.

19. The NOR gate digital circuit as set forth in claim 16 comprising:
two (2) NPN transistors, three (3) PNP transistors and three (3) current sources connected as follows:
the base of a first PNP transistor and the base of a second PNP transistor are connected to one end of a first current source and this connection is the input of the digital circuit, where opposite end of said current source is connected to a reference voltage which can include ground,
the collectors of said first PNP transistor and said second PNP transistors are connected to said reference voltage;
the emitters of said first PNP transistor and said second PNP transistor are connected to the base of first NPN transistor and to the emitter of second NPN transistor;
the emitter of said first NPN transistor is connected to said reference voltage;
the base of said second NPN transistor is connected to the collector of said first NPN transistor and to one end of a second current source, where said second current source is connected to a predetermined positive supply voltage;
the base of said third PNP transistor is connected to the collector of said second NPN transistor;
the emitter of said third PNP transistors is connected to a predetermined positive supply voltages and;
the collector of said third PNP transistors is connected to is the output of the device and is further connected to a third current source where opposite end of said third current source is connected to said reference voltage;
whereby the absence of an input signal causes the output to saturate to the positive supply voltage with a current capability of beta of said first PNP transistor times beta of said third PNP transistor times the current drawn by said first current source;
whereby the presence of a high input signal the output goes into a off state where there is some current being output which can swamped by the said third current source as such output current is of the order of the current being supplied by said second current source;
whereby the ratio of output current to required input current is basically equal to the beta of said first PNP transistor times the beta of said third PNP transistor and such figure called fan-out is on the order of 10,000;
whereby said digital circuit can operate on a voltage below 1.5 volts.

20. The device as detailed in claims 1 wherein said means comprising:
two bipolar transistors of like type or conductivity;
said terminal 1 is the connection of the base of said second transistor and the collector of said first transistor;
said terminal 2 is the emitter of said first transistor;
said terminal 3 is the collector of said second transistor;
said terminal 4 is the connection of the base of said first transistor and the emitter of said second transistor, and;
thereby
said terminal 1 accepts a current of predetermined direction;
said terminal 2 is receptive to an input signal;
said terminal 3 causes a current to flow in a predetermined direction;
said terminal 4 concurrently produces an output voltage and current in response to the voltage and current at said terminal 2 and senses said voltage and current at said terminal 4 and to adjusts said voltage and current at said terminal 2 and said current at said terminal 3; and
whereby said device can be used to create amplifiers, cascoding devices, buffers, regulators, and digital circuits with new topologies.

21. The device as detailed in claims 1 wherein said means comprising:
a bipolar transistor and a FET transistor of like type or conductivity;
said terminal 1 is the connection of the gate of said FET transistor and the collector of said bipolar transistor;
said terminal 2 is the emitter of said bipolar transistor;
said terminal 3 is the drain of said FET transistor;
said terminal 4 is the connection of the base of said bipolar transistor and the source of said FET transistor, and;
thereby
said terminal 1 accepts a current of predetermined direction;
said terminal 2 is receptive to an input signal;
said terminal 3 causes a current to flow in a predetermined direction;
said terminal 4 concurrently produces an output voltage and current in response to the voltage and current at said terminal 2 and senses said voltage and current at said terminal 4 and to adjusts said voltage and current at said terminal 2 and said current at said terminal 3; and
whereby said device can be used to create amplifiers, cascading devices, buffers, regulators, and digital circuits with new topologies.
